(19) United States
(12) Patent Application Publication
(10) Pub. No.: US 2025/0212365 A1
(43) Pub. Date: Jun. 26, 2025

(54) HEAT DISSIPATION SYSTEMS FOR ELECTRONIC DEVICES AND RELATED METHODS

(71) Applicant: Intel Corporation, Santa Clara, CA (US)

(72) Inventors: Gaurav Patankar, Gilbert, AZ (US); Krishnendu Saha, Bangalore (IN); Srinivasa Rao Konakalla, Bangalore (IN); Samarth Alva, Bangalore (IN); Arnab Sen, Bangalore (IN); Jeff Ku, Taipei (TW); Ravishankar Srikanth, Bangalore (IN); Prasanna Pichumani, Bangalore (IN)

(21) Appl. No.: 18/394,848

(22) Filed: Dec. 22, 2023

(51) Int. Cl. H05K 7/20; G06F 1/20

(52) U.S. Cl. CPC H05K 7/20327; G06F 1/203; H05K 7/20309; H05K 7/20336; H05K 7/20381

(57) ABSTRACT

Heat dissipation systems, apparatus, articles of manufacture, and methods are disclosed. An example computing device includes a display, a keyboard, processor circuitry, and a dual-phase heat dissipation system. The dual-phase dissipation system includes a housing defining a chamber, a fluid inlet, and a fluid outlet. The chamber receives a working fluid via the fluid inlet. A pump fluidly couples to the fluid inlet and the fluid outlet of the housing. The pump is to receive the working fluid via the fluid outlet of the housing and increase at least one of a flow rate or volume of the working fluid at the fluid inlet.

### FIELD OF THE DISCLOSURE

This disclosure relates generally to electronic devices, and, more particularly, to heat dissipation systems for electronic devices and related methods.

### BACKGROUND

Electronic devices utilize thermal systems to manage thermal conditions for maintaining optimal efficiency and/or performance. To manage thermal conditions, electronic devices employ thermal cooling systems that cool electronic components of the electronic devices during use.

### BRIEF DESCRIPTION OF THE DRAWINGS

FIG. 1 is a perspective view of an example electronic device having an example heat dissipation system in accordance with teachings of this disclosure.

FIG. 2 is a front view of example components of the example electronic device of FIG. 1 including an example implementation of the example heat dissipation system of FIG. 1.

FIG. 3 is a perspective view of an example implementation of the heat dissipation system of FIG. 2.

FIG. 4A is a top view of the example heat dissipation system of FIG. 2 with a portion of an example housing removed.

FIG. 4B is a cross-sectional view of an example vapor chamber of the example heat dissipation system taken along line 4B-4B of FIG. 4A.

FIG. 5 is another top view of the example heat dissipation system of FIGS. 2, 3, 4A and 4B.

FIG. 6 is a perspective view of another example implementation of the heat dissipation system of FIG. 1.

FIG. 7 is a perspective view of another example implementation of the heat dissipation system of FIG. 1.

FIG. 8 is a cross-sectional front view of another implementation of the heat dissipation system of FIG. 1.

FIG. 9 is a cross-sectional front view of yet another example implementation of the heat dissipation system of FIG. 1.

FIG. 10 is a block diagram of an example implementation of an example thermal manager circuitry of the example electronic device 100 of FIG. 1.

FIG. 11 is a flowchart representative of example machine readable instructions and/or example operations that may be executed, instantiated, and/or performed by example programmable circuitry to implement the thermal manager circuitry of FIG. 10.

FIG. 12 is a block diagram of an example processing platform including programmable circuitry structured to execute, instantiate, and/or perform the example machine readable instructions and/or perform the example operations of FIG. 9 to implement the thermal manager of FIG. 10.

FIG. 13 is a block diagram of an example implementation of the programmable circuitry of FIG. 12.

FIG. 14 is a block diagram of another example implementation of the programmable circuitry of FIG. 12.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Over the past years, personal computing devices have decreased in size (e.g., employ a smaller and lighter form factor) while computing power (e.g., running more powerful processors) has increased. In these types of personal computing devices, thermal management is important to both computing performance and user experience. For example, during operation of an electronic device (e.g., a desktop computer, a server, a laptop, a tablet, a mobile device, a headset, a virtual reality headset, wearable devices, electronic glasses, etc.), hardware components, such as a processor, a graphics card, a battery and/or other electronic components disposed in a body or housing of the device, generate heat. Heat generated by the hardware components of the electronic device can cause a temperature of one or more electronic components to exceed operating temperature limits of the one or more electronic components. In some instances, heat generated by the electronic device (e.g., a mobile or portable device) can cause portions of an exterior surface, or skin, of a device housing to increase and become warm or hot to a user's touch. Thus, as processor power increases and device form factor decreases, the ability to dissipate generated heat from the processor improves device performance. For example, failing to effectively reject generated heat can reduce or decrease performance of the electronic device that can be noticed by users.

To prevent overheating of the hardware components and/or damage to the device when the user touches or places one or more portions of the user's body proximate to the skin of the device and/or components of the device accessible via the exterior surface of a housing such as a tablet, electronic devices often employ a thermal management system to dissipate heat from the electronic device. Known thermal systems include active cooling systems or passive cooling systems. Active cooling systems employ forced cooling fluids to increase a rate of fluid flow, which increases a rate of heat removal. For example, to exhaust heat or heated air generated within the body of the electronic device and cool the electronic device, active cooling systems often employ external devices such as fans or blowers, forced liquid, thermoelectric coolers, etc. Passive cooling systems employ natural convection and heat dissipation by utilizing thermal solutions such as heat sinks and/or heat spreaders to increase (e.g., maximize) radiation and convection heat transfer. Passive cooling systems are significantly less expensive than active cooling systems, do not require power to operate, and provide space saving benefits.

Active cooling systems employ forced cooling fluids (e.g., convenction) to increase a rate of fluid flow, which increases a rate of heat removal. For high power laptops may be cooled by transporting heat from a processor (e.g., a system on chip (SoC)) and other heat sources to the heat exchanger by using a fan to remove heated air from the system and/or electronic device. For example, some thermal management systems employ single-phase convective heat transfer systems (e.g., a liquid based cooling pipe) to transport heat from the processor to a heat exchanger. The liquid does not evaporate within the piping system. In such systems, liquid is circulated through a piping system via a pump. However, such systems can be disadvantageous because a large fluid flow rate is needed to effectively remove heat via the liquid, resulting in usage of a larger sized pump. Larger sized pumps consume greater amounts of space (e.g., limited space) in a housing and/or increase acoustic output levels (e.g., greater than 25 decibels (dBA)) when in use. Additionally, a thermal load that can be carried by liquid is less than a thermal load that can be carried by a vapor. Thus, heat transport systems that are single-phase, liquid based systems are less efficient than vapor based systems.

Two-phase convective heat transport systems (e.g., vapor chambers and/or heat pipes employ) employ liquid and vapor to transport heat from a heat source. Such systems are advantageous over single-phase liquid systems because vapor can carry a greater amount of heat than liquid. Thus, two-phase heat transport systems can provide greater heat transfer efficiency than single-phase or liquid based systems. In these passive transport devices, the liquid evaporates by absorbing heat from a heat source (e.g., an evaporator area) and travels to a heat sink area, where it condenses at a cooler, heat exchanger area (e.g., a condenser area). The condensed liquid trickles back to the heat source area through a wick via capillary action. A wick has a porous structure that employs capillary forces to transfer liquid (e.g., water) from one end of the wick to another end (e.g., an opposite end). As used herein, “capillary action” is the process of a liquid flowing in a narrow space without the assistance of, or even in opposition to, any external forces like gravity. For example, capillary action occurs because of forces (e.g., surface tension) between the liquid and surrounding solid surfaces. If the diameter of a tube or material is sufficiently small, a combination of surface tension (which is caused by cohesion within the liquid) and adhesive forces between the liquid and material wall act to propel a liquid along a length of the material.

Vapor chambers and/or heat pipes are dual-phase heat transport systems. A thermal load (e.g., a maximum thermal load (Qmax)) that a vapor chamber or heat pipe can carry is dependent on the mass flow rate of a heat transfer medium or working fluid (e.g., a liquid, water, etc.) from a condenser to an evaporator. As used herein, “heat transfer medium” and “working fluid” are used interchangeably. Specifically, an amount of working fluid in the vapor chamber or heat pipe is fixed and a flow rate is established by capillary forces of the wick. Therefore, heat transport capacity is limited by working fluid capacity and by capillary action of the wick structure, which determines a thermal load (e.g., maximum thermal load (Qmax)) of the heat transport device. A thermal load can be increased by increasing the volume of the working fluid and providing larger wick structure for greater capillary action. However, such increases of working fluid (e.g., a liquid such as water) and/or wick structures causes an increase in an overall thickness (e.g., in a z-direction) of the heat transport device (e.g., the vapor chamber/heat pipe). Thus, the greater the amount of heat to be transported, the greater the thickness of the vapor chamber/heat pipe. However, increasing a thickness of the vapor chamber/heat pipe (e.g., in the z-direction) leads to reduced air gaps inside a housing (e.g., a base or a notebook) resulting in higher skin temperatures. To keep the skin temperatures to desired levels (e.g., the same temperature compared to the non-reduced air gap), a thickness of the housing (e.g., notebook) may be increased and/or a size and/or speed of the fan may increased, which results in a device having a greater thickness (e.g., in the z-direction). Additionally or alternatively, a fan with greater fan output (e.g., a larger sized fan and/or increased fan speed) can be employed. However, larger sized fans and/or operation of the fan(s) at higher speeds generate undesired audible acoustic noise.

Example heat transfer apparatus disclosed herein provide heat transport devices (e.g., thin heat pipes and/or vapor chambers) that can cool a greater range of thermal loads without increasing dimensional aspects (e.g., thicker) of the heat transfer apparatus (e.g., heat pipe/vapor chamber). As a result, example heat transfer apparatus disclosed herein enable thinner, quieter, and/or more efficient performing electronic devices (e.g., notebooks) having cooler skin temperatures. Specifically, example heat transfer apparatus disclosed herein employ wicking material (e.g., a wick or wick pad) to collect condensation and distribute or channel condensation to a remote location positioned away from certain electronic components (e.g., processor(s), system on chip (SOC), circuit board, etc.). In some examples, condensed water collected by the wick or wicking material can be evaporated (e.g., via heat, fans, blowers, etc.) from the wicking material. A flow rate of the wick is established by capillary forces. Example heat transfer apparatus disclosed herein provide a relatively high thermal load (e.g., Qmax) in a relatively thin vapor chamber/heat pipe by increasing or boosting a capillary action of wick based heat transfer device.

To increase capillary action, example heat transfer apparatus disclosed herein provide for dynamic adjustment of thermal load output of a heat transport device (e.g., a vapor chamber and/or heat pipe). To dynamically adjust a thermal load output of the heat transport device, thermal management systems disclosed herein employ a pump (e.g., a micro, silent pump). For example, when an increased amount of heat transfer or heat removal is needed during a high-performance operation (e.g., a processor operating at greater than 20 watts) of an electronic device, example thermal management systems disclosed herein employ the pump to increase a fluid flow rate of the working fluid through the wick structure enabling the heat transfer system to operate at a higher thermal load. For instance, example pumps disclosed herein increase fluid flow from a condenser region to an evaporator region.

Some example heat transfer apparatus disclosed herein employ a reservoir to dynamically adjust (e.g., increase or decrease) and/or supplement an amount of working fluid (e.g., a volume of liquid) of the heat transfer apparatus. For instance, the pump can employ fluid from the reservoir to operate the heat transfer apparatus with increased efficiency (e.g., optimum efficiency) based on a needed workload. The reservoir and/or the pump can be positioned externally from the vapor chamber and/or the heat pipe so that the reservoir and/or pump do not increase a thickness of the vapor chamber and/or heat pump. Employing higher thermal loads (Qmax) in example heat transfer apparatus disclosed herein (e.g., thin vapor chamber/heat pipe) allows electronic devices to be thinner (e.g., in the z-direction), operate quieter (e.g., less noise and/or decibels) and/or cooler than known devices, resulting in lower operating temperatures and improved or more efficient performance.

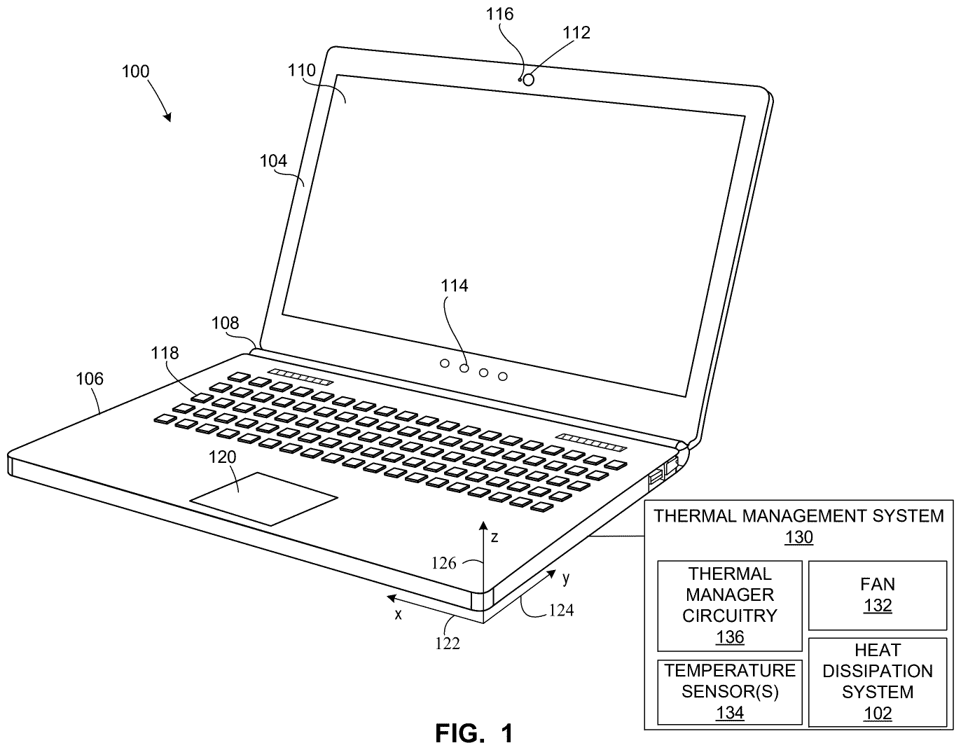

FIG. 1 illustrates an example electronic device 100 having an example heat dissipation system 102 (e.g., a heat transport device) constructed in accordance with teachings of this disclosure. The electronic device 100 of the illustrated example is a computing device such as, for example, a laptop. The electronic device 100 of the illustrated example includes a first housing 104 (e.g., a lid, a screen, display, touchscreen etc.) coupled to a second housing 106 (e.g., a base, a keyboard, c-cover) via a hinge 108. The hinge 108 enables the first housing 104 to rotate or fold relative to the second housing 106 between a closed or stored position (e.g., where the second housing 106 is aligned or parallel with the first housing 104) and an open position as shown in FIG. 1 (e.g., where the second housing 106 is non-parallel relative to the first housing 104). In the open position, the second housing 106 can rotate relative to the first housing 104 about the hinge 108 to a desired viewing angle. The first housing 104 carries a display 110, a camera 112, speakers 114, and a microphone 116. In some examples, the display 110 is a touch screen.

To enable user inputs, the second housing 106 of the illustrated example includes a keyboard 118 and a track pad 120 exposed via the second housing 106 (e.g., opposite a bottom surface). The second housing 106 houses electronic and/or hardware components (e.g., the heat dissipating system 102, I/O connector(s), a graphics card, a battery, light emitting diodes, memory, a storage drive, an antenna, cooling fans, a central processing unit (CPU), a circuit board, etc.)). The second housing 106 has a width in an x-direction 122, a length in a y-direction 124, and a height in a z-direction 126 (e.g., a depth in a z-direction). References to the x-y-z direction throughout this specification pertain a direction along the width in the x-direction 122, the length in the y-direction 124, and the height in the z-direction 126, respectively.

The components of the electronic device 100 (e.g., the processor, a video graphics card, etc.) generate heat during operation of the electronic device 100. To dissipate or spread heat generated by the hardware components during operation of the electronic device 100, the electronic device 100 of the illustrated example employs a thermal management system 130. The thermal management system 130 of the illustrated example is an active cooling system that includes a fan 132 (e.g., one or more fans). The thermal management system 130 of the illustrated example includes temperature sensor(s) 134 to measure temperature(s) associated with the hardware components of the electronic device 100 (e.g., a processor), a skin enclosure (e.g., the first housing 104 and/or the second housing 106), and/or other component(s). The thermal management system 130 of the illustrated example operates a fan and/or fan speed based on one or more feedback signals received by the temperature sensor(s).

Additionally, the heat dissipation system 102 of the illustrated example dissipates heat generated by the components stored within the second housing 106. The heat dissipation system 102 of the illustrated example is a two-phase system (e.g., a liquid-vapor system, a dual-phase heat transport system). The thermal management system 130 can dynamically adjust (e.g., increase or decrease) at least one of a fluid flow rate and/or a volume of a working fluid employed by the heat transfer device during operation. For instance, the heat dissipation system 102 can operate in a passive mode or an active mode. As used herein, the heat transport device operates in a passive mode absent external forces to increase either a flow rate or volume of a working fluid of the heat transport device. As used herein, the heat transport device operates in an active mode via employment of external forces to increase either a flow rate or volume of a working fluid of the heat dissipating system 102.

In operation, thermal manager circuitry 136 controls the fan 132 in view of one or more thermal constraints for the electronic device 100 that define temperature settings for the electronic and/or hardware components of the electronic device 100. For example, the thermal manager circuitry 136 of the illustrated example processes temperature data generated by the temperature sensor(s) 134 for one or more of the electronic and/or hardware components and operates the fan 132 to reduce a temperature of the one or more electronic and/or hardware components in response to detecting that a temperature of the one or more electronic and/or hardware components is approaching a maximum desired operating temperature. The fan 132 provides means for cooling and/or regulating a temperature of the electronic and/or hardware components (e.g., a processor) of the electronic device 100 in response to temperature data generated by the temperature sensor(s) 134. In some instances, the thermal manager circuitry 136 can be configured to operate the fan 132 to reduce a temperature of a skin enclosure. For instance, the thermal manager circuitry 136 can adjust (e.g., increase or decrease) a speed output of the fan 132 based on one or more feedback signals of the temperature sensor(s) 134. For example, the thermal manager circuitry 136 can cause the fan 132 to operate a lower speed when less heat removal is needed and/or when a measured temperature of the housing or the components is less than a temperature threshold and can cause the fan to operate at a higher speed when more heat removal is needed and/or when a measured temperature of the housing and/or components is greater than the temperature threshold.

The thermal manager circuitry 136 can operate the heat dissipation system 102 based on a detected condition of the electronic device 100. For example, the detected condition can be compared to a condition threshold. For example, the detected condition of the electronic device 100 can be a power output (e.g., Watts) of one or more electronic or hardware components (e.g., a CPU), a temperature of an electronic or hardware component, a skin temperature of a housing, a fan speed of a fan, and/or any other desired operating condition(s). The threshold values can be stored in memory and/or a look-up table. In some examples, the thermal manager circuitry 136 can operate the heat dissipation system 102 in an active heat dissipation phase (e.g., to increase a flow rate of a working fluid) or a passive heat dissipation phase.

In some examples, the thermal manager circuitry 136 compares a detected condition and/or detected threshold based on a power threshold of one or more electronic and/or hardware components of the electronic device. For example, the thermal manager circuitry 136 can operate the heat dissipation system 102 based on a detected power (e.g., watts) of the CPU in comparison to power threshold. In some examples, the thermal manager circuitry 136 can operate the heat dissipation system 102 based on a detected temperature (e.g., a skin enclosure temperature, a CPU temperature, etc.) in comparison to a temperature threshold. In some examples, the thermal manager circuitry 136 can operate the heat dissipation system 102 based on detected fan speed of the fans 132 in comparison to a fan speed threshold. In some examples, the thermal manager circuitry 136 operates the heat dissipation system 102 based on any other condition of the electronic device 100.

Although the example electronic device 100 of the illustrated example is a laptop, in some examples, the electronic device 100 can be a foldable tablet (e.g., having a two housings), a desktop computer, a mobile device, a cell phone, a smart phone, a hybrid or convertible PC, a personal computing (PC) device, a server, a modular compute device, a digital picture frame, a graphic calculator, a smart watch, and/or any other electronic device that has a hinge 108 that pivotally connects a first housing and a second housing.

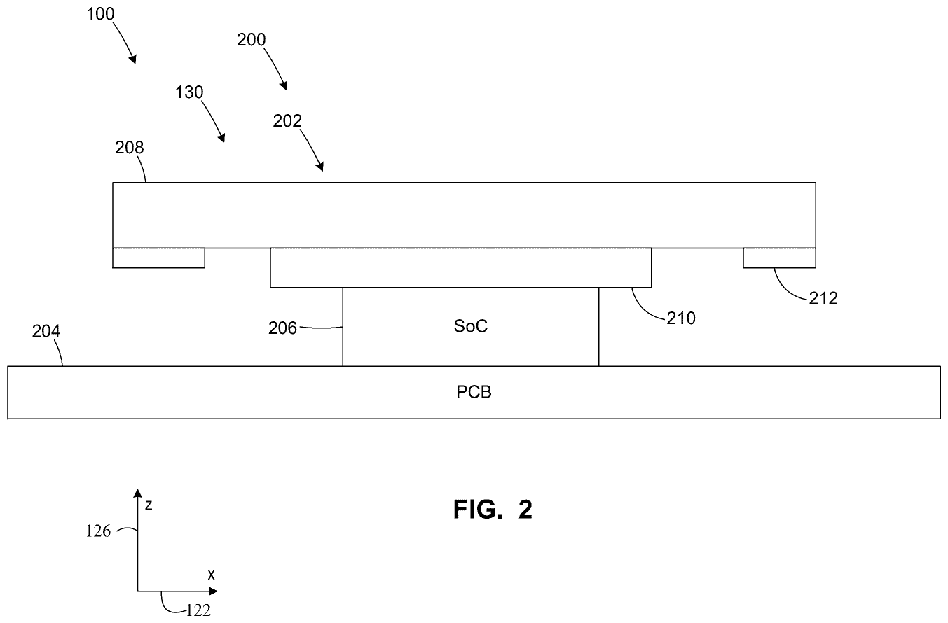

FIG. 2 is a partial, front view of example electronic and/or hardware components 200 and an example heat dissipation system 202 (e.g., a thermal transport device) disclosed herein that can implement the example thermal management system 130 of the electronic device 100 of FIG. 1. The heat dissipation system 202 (e.g., a dual-phase heat transport device or system) can implement the example heat dissipation system 102 of FIG. 1. The example components of the illustrated example include a printed circuit board (PCB) 204 (e.g., a motherboard, etc.) and a central processing unit (CPU) 206 (e.g., a system on chip (SOC), a processor die, etc.) coupled to the PCB 204 that executes software to interpret and/or output response(s) based on the user input event(s) (e.g., touch event(s), keyboard input(s), etc.). The CPU 206 can include any type of processing or processor circuitry, such as a central processing unit (CPU), graphics processing unit (GPU), microprocessor, microcontroller, accelerator, field-programmable gate array (FPGA), etc. In some examples, the CPU 206 of the illustrated example can exceed 20 watts of power.

The heat dissipation system 202 of the illustrated example dissipates or spreads heat generated by the electronic and/or hardware components 200 and/or the CPU 206 during operation of the electronic device 100. The heat dissipation system 202 of the illustrated example is a vapor chamber 208. For example, the vapor chamber 208 of the illustrated example is positioned on (e.g., directly or indirectly) or over (e.g., above) the CPU 206 to remove the heat generated by the CPU 206. In the illustrated example, the CPU 206 is positioned between the PCB 204 and the vapor chamber 208. A pedestal 210 is positioned between the CPU 206 and the vapor chamber 208. To cool a heat transfer medium or working fluid of the vapor chamber 208, the thermal management system 130 of the illustrated example employs heat exchangers 212. The heat exchangers 212 can be heat fins, radiators, etc. Additionally, the thermal management system 130 of the illustrated example includes one or more fans 132 (FIG. 1) to provide a cooling fluid to remove heat from the heat exchangers 212 and, thus, the vapor chamber 208. For example, the cooling fluid of the illustrated example is provided by fan air that is drawn through the heat exchangers 214 to cool or remove heat from the heat transfer medium within the vapor chamber 208. In some examples, the heat exchanger 214 provide means for cooling or removing waste heat from a heat transfer medium.

In some examples, the thermal management system 130 can include a heat spreader interposed between the processor and the vapor chamber. The heat spreader can be a block of thermally conductive material including, for example, copper (Cu), aluminum (Al), and/or any other thermally conductive metal(s), material(s) and/or alloy(s). Further, in some examples, a heat spreader can be implemented as a thermal interposer (e.g., copper interposer). In some examples, the thermal management system 130 can include any other structure for transferring heat and/or spreading heat from the CPU 206 and/or components to the vapor chamber. In some examples, the heat spreader can be positioned between (e.g., on top of) the vapor chamber 208 and a chassis of the second housing 106 (FIG. 1) to facilitate heat removal from the vapor chamber 208, the CPU 206 and/or the electronic and/or hardware components 200. In some examples, the thermal management system 130 can be a heat pipe. Thus, example thermal management system 130 of the electronic device 100 of FIG. 1 can be configured with a heat pipe instead of the vapor chamber 208.

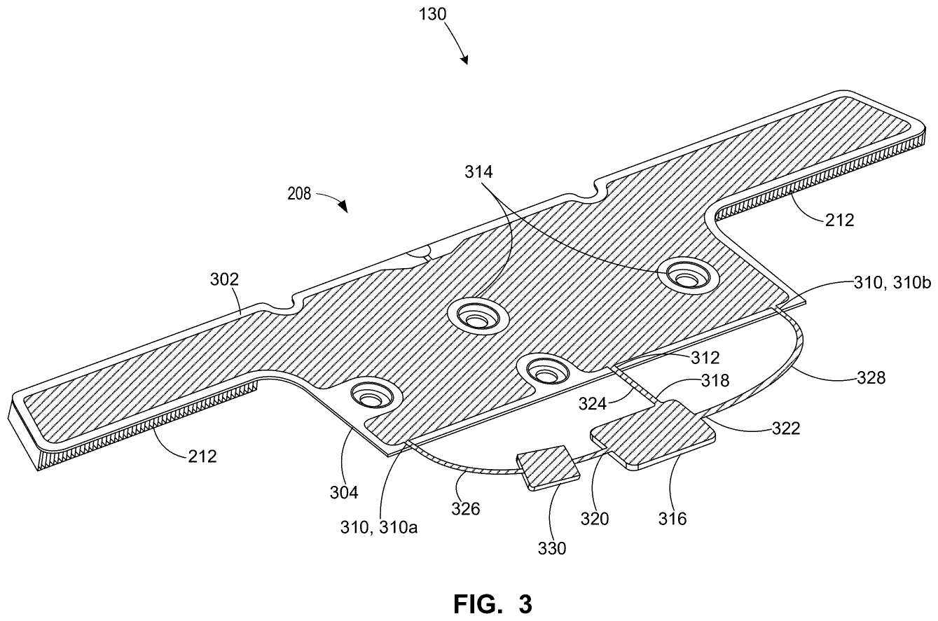

FIG. 3 is a perspective view of the example heat dissipation system 202 of FIG. 2. The heat dissipation system 202 of the illustrated example includes the vapor chamber 208. The vapor chamber 208 of the illustrated example is a heat sink that includes a shell or housing (e.g., a metal enclosure). The housing 302 and/or the vapor chamber 208 of the illustrated example can be composed of brass, copper, aluminum, an alloy and/or any other suitable thermally conductive material(s) for transferring and/or spreading heat. The housing 302 of the illustrated example is vacuum sealed. For example, a perimeter edge 304 of the housing 302 is hermetically sealed. The heat exchangers 212 are coupled to a first surface 306 (e.g., a lower surface) of the housing 302 opposite a second surface 308 (e.g., an upper surface). The housing 302 of the illustrated example includes a fluid outlet 310 and a housing inlet 312. Specifically, the housing 302 of the illustrated example includes a first housing outlet 310a and a second housing outlet 310b. The vapor chamber 208 and/or the housing 302 of the illustrated example has a T-shape profile. The vapor chamber 208 of the illustrated example includes apertures 314 to receive fasteners (e.g., standoffs) that couple to the PCB 204 (FIG. 2). The fasteners (e.g., standoffs) separate the PCB 204 from the vapor chamber 218 to provide a gap between the PCB 204 and the vapor chamber 208 for the CPU 206.

To increase a flow rate and/or volume of a heat transfer medium (e.g., a working fluid), the heat dissipation system 202 of the illustrated example includes a pump 316. Specifically, the pump 316 is fluidly coupled to the vapor chamber 208. The pump 316 includes a pump outlet 318 coupled to the housing inlet 312 of the housing 302. The pump 316 of the illustrated example includes a first pump inlet 320 coupled to the first housing outlet 310a and a second pump inlet 322 coupled to the second housing outlet 310b. The vapor chamber 208 of the illustrated example includes a first fluid line 324 (e.g., a fluid path) to fluidly couple the pump outlet 318 and the housing inlet 312, a second fluid line 326 (e.g., a fluid path) to fluidly couple the first pump inlet 320 and the first housing outlet 310a, and a third fluid line 328 (e.g., a fluid path) to fluidly couple the second pump inlet 322 and the second housing outlet 310b. The fluid lines 324-328 of the illustrated example can be pipes, tubing, copper pipes, reinforced silicon tubes, and/or any other flow path(s).

To store the heat transfer medium, the heat dissipation system 202 of the illustrated example includes a fluid reservoir 330. The fluid reservoir 330 of the illustrated example is fluidly coupled to the pump 316. For example, the fluid reservoir 330 of the illustrated example is interposed in the second fluid line 326 upstream from the pump 316 (e.g., the pump outlet 318). In some examples, the fluid reservoir 330 can be interposed in the first fluid line 324 downstream from the pump outlet 318, in the third fluid line 328, and/or any other location (e.g., remote location) from the pump 316. The fluid reservoir 330 of the illustrated example is a fluid tank and can be made of metal, plastic and/or any other material(s). In some examples, the fluid reservoir 330 can be positioned and/or formed inside the vapor chamber 208.

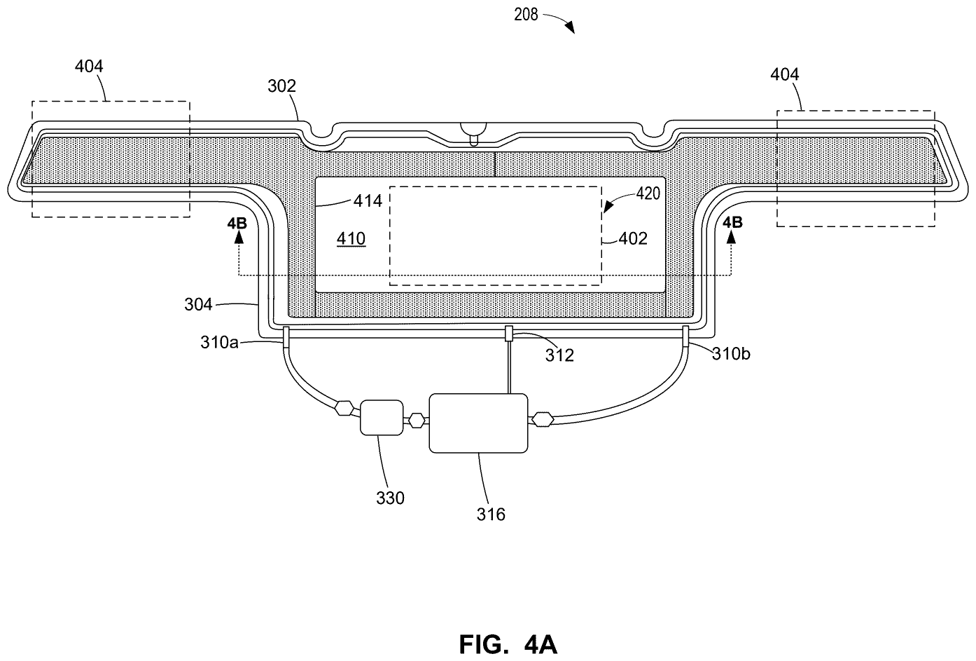

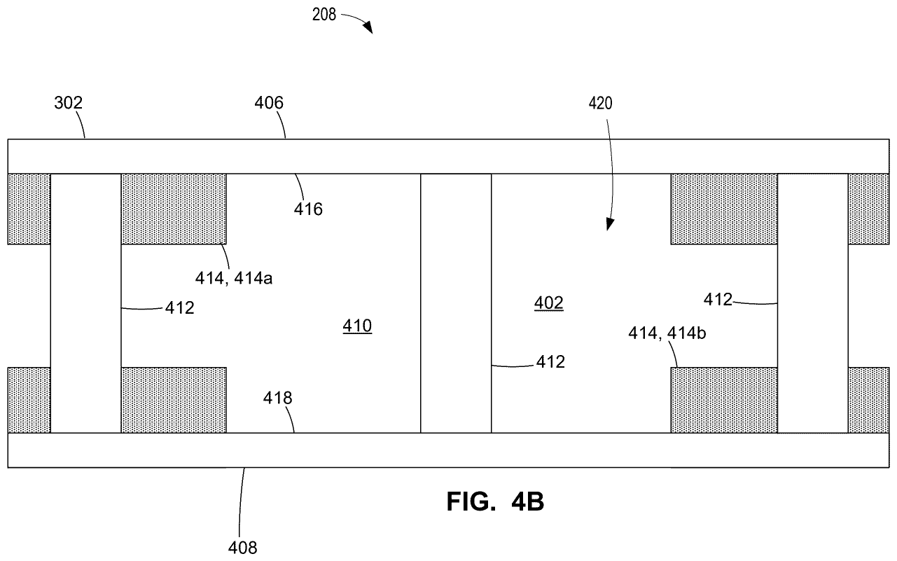

FIG. 4A is a top view of the heat dissipation system 202 of FIGS. 2 and 3. FIG. 4B is a cross-sectional view of the vapor chamber 208 taken along line 4B-4B of FIG. 4A. In FIG. 4A, for clarity, an example first plate 406 (FIG. 4B) of the housing 302 is removed. The vapor chamber 208 of the illustrated example includes an evaporator area 402 (e.g., an evaporator) and a condenser area 404 (e.g., condenser). Specifically, the evaporator area 402 is adjacent (e.g., above) the CPU 206 and the condenser area 404 is at a remote location from the evaporator area 402 adjacent to the heat exchangers 212 (FIG. 3).

The housing 302 of the vapor chamber 208 of the illustrated example includes a first plate 406 (e.g., an upper plate) and a second plate 408 (e.g., a lower plate) opposite the first plate 406. The first plate 406 and the second plate 408 (e.g., the housing 302) defines an evaporator chamber 410. The housing 302 and/or the evaporator chamber 410 of the illustrated example receives a heat transfer medium (e.g., a working fluid, water, etc.). For example, the evaporator chamber 410 can define an evaporator surface on which the heat transfer medium (e.g., condensed liquid) is channeled or provided. The heat transfer medium of the illustrated example operates in a first phase (e.g., vapor phase) when evaporated at the evaporator area 402 and a second phase (e.g., liquid phase or condensed liquid) when condensed at the condenser area 404. The first plate 406 and the second plate 408 are relatively thin (e.g., in the z-direction) and/or a pressure in the evaporator chamber 410 can be below atmospheric pressure. To support (e.g., a structural integrity of) the first plate 406 and the second plate 408, the vapor chamber 208 of the illustrated example includes a plurality of pillars or support beams 412 (e.g., vertical pillars in the orientation of FIG. 4B) spaced within the evaporator chamber 410.

To transfer condensed heat transfer medium from the condenser area 404 to the evaporator area 402, the vapor chamber 208 of the illustrated example includes an internal wicking material or wicking material 414. The wicking material 414 of the illustrated example is attached to inner walls of the housing 302. The wicking material 414 provides an internal flow path that moves moisture from cooler regions or locations (e.g., a condenser or the condenser area 404) to warmer regions or locations (e.g., an evaporator of the evaporator area 402) for evaporation via capillary action. Thus, the wicking material 414 extends from the condenser area 404 to the evaporator area 402. The housing 302 seals the wicking material 414 and a heat transfer medium within the housing 302. The wicking material 414 of the illustrated example is a pad or wicking medium. The wicking material 414 of the illustrated example includes a first wick 414a provided on the first plate 406 and a second wick 414b provided on the second plate 408. The first wick 414a and/or the second wick 414b of the illustrated example moves heat transfer medium or working fluid (e.g., condensed liquid) through the evaporator chamber 410 via capillary action.

In the illustrated example, the wicking material 414 does not extend across the entirety of the evaporator chamber 410. In other words, the first wick 414a is provided on a partial portion of the first plate 406 and the second wick 414b is provided on a partial portion of the second plate 408. In the illustrated example, the wicking material 414 is positioned along or adjacent to the perimeter edge 304 of the vapor chamber 208. For instance, the wicking material 414 can have a width of approximately between ½ inch and 2 inches and can be positioned along the perimeter edge 304 of the housing 302. As a result, an internal or inner surface 416 of the first plate 406 is exposed and/or does not include the wicking material 414 and an inner or internal surface 418 of the second plate 408 is exposed and/or does not include wicking material 414. In other words, a center area 420 of the evaporator chamber 410 (e.g., defining at least a portion of the evaporator area 402) does not include the wicking material 414. In this matter, the evaporator chamber 410 can include a larger volume and/or non-wicking area. Providing the evaporator chamber 410 with a larger sized volume enables a greater amount of heat transfer medium evaporation or vapor, which results in a larger amount of heat absorption and, thus, a more efficient heat transfer device. For example, a smaller volume of the evaporator chamber 410 consumed by the wicking material 414 provides a larger sized chamber and/or vapor space. In operation, such additional vapor space reduces a vapor pressure drop when the liquid heat transfer medium transfers from liquid to vapor, which enables the vapor to carry larger amount of heat and thereby increasing a performance efficiency of the vapor chamber 208. The wicking material 414 of the illustrated example is fluidly coupled to the housing inlet 312, the first housing outlet 310a, and the second housing outlet 310b. The wicking material 414 extends to and/or near the evaporator area 402 and/or in fluid communication with the housing inlet 312.

To increase a fluid flow rate (e.g., a velocity) of the heat medium transfer through the wicking material 414 and/or the vapor chamber 208, the heat dissipation system 202 of the illustrated example includes the pump 316. Additionally, the heat dissipation system 202 of the illustrated example includes the fluid reservoir 330 to retain or hold at least a portion (e.g., between 20 percent and 40 percent by volume) of the heat transfer medium of the vapor chamber 208. The fluid reservoir 330 is fluidly coupled to the vapor chamber 208 and the pump 316. The fluid reservoir 330 stores heat transfer fluid (e.g., condensed fluid or water) externally from the vapor chamber 208. To this end, the pump 316 of the illustrated example causes (e.g., draws) fluid from the fluid reservoir 330 to flow through the vapor chamber 208. As a result, the pump 316 can increase an amount of working fluid (e.g., a mass flow rate) that can flow through the vapor chamber 208 by drawing fluid from the fluid reservoir 330 and/or increasing a fluid flow rate of the working fluid through the vapor chamber 208. When the pump 316 is not used and/or the pump 316 operates in a low power mode, the fluid reservoir 330 can store excess working fluid externally from the vapor chamber 208. Thus, the fluid reservoir 330 can increase the volume of working fluid of the vapor chamber 208 without needing to increase a volume of the vapor chamber 208 and/or a wicking material 414of the vapor chamber 208. The pump 316 of the illustrated example can be a piezoelectric pump that can operate at relatively low acoustic levels (e.g., less than 25 decibels dBA). The pump 316 of the illustrated example can provide a flowrate of between approximately 5 microliters per min and 4,000 microliters per minute. The pump 316 can weigh approximately 1 to 3 grams and can have a length of approximately 30 millimeters (e.g., in the x-direction 122), a width of approximately 15 millimeters (e.g., in the y-direction 124), and a thickness of approximately 3.5 millimeters (e.g., in the z-direction 126). Thus, the pump 316 does not increase a thickness of the electronic device 100 in the z-direction.

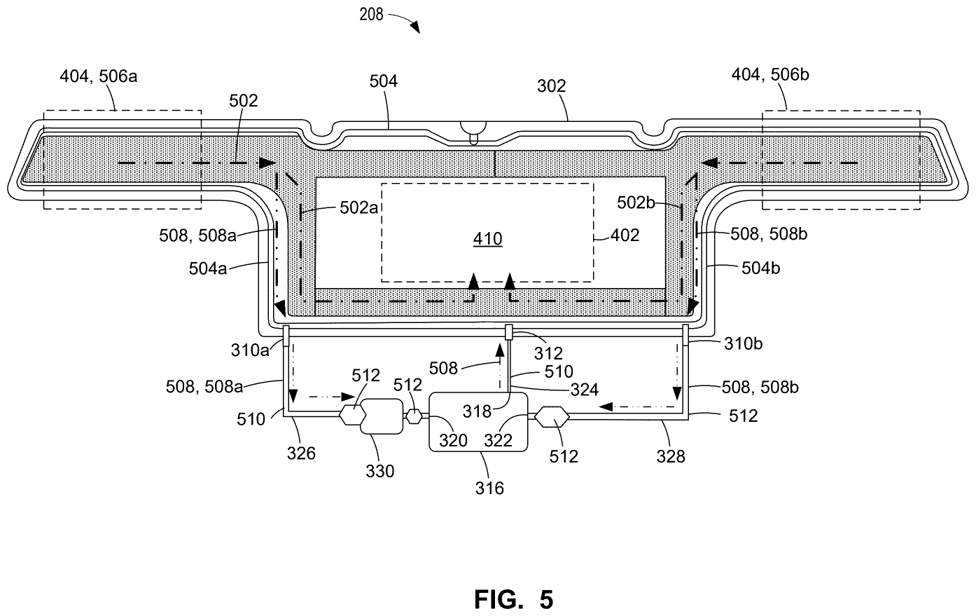

FIG. 5 is another top view of the example vapor chamber of FIGS. 2, 3, 4A and 4B. To transfer condensed heat transfer medium from the condenser area 404 to the evaporator area 402, the vapor chamber 208 of the illustrated example includes a primary flow path 502. The primary flow path 502 of the illustrated example is schematically illustrated by a dot-dash line in FIG. 5. Specifically, the primary flow path 502 of the illustrated example is provided by the wicking material 414 (e.g., an internal wicking material) attached to inner walls of the housing 302. The wicking material 414 provides an internal flow path that moves moisture from cooler regions or locations (e.g., a condenser or the condenser area 404) to warmer regions or locations (e.g., an evaporator of the evaporator area 402) for evaporation via capillary action. Thus, the vapor chamber 208 includes the primary flow path 502 (e.g., provided by the wicking material 414) to enable condensed liquid (e.g., water) to flow from the condensed area 404 toward a heat source (e.g., the evaporator area 402). The wicking material 414 circulates or moves (e.g., passively moves) condensed heat transfer medium or working fluid in the vapor chamber 208 (e.g., via capillary action). The primary flow path 502 is enclosed (e.g., completely enclosed or positioned) within the housing 302.

The primary flow path 502 and/or the housing 302 of the illustrated example includes one or more channels 504 around or adjacent to the perimeter edge 304 of the housing 302 to facilitate fluid flow toward the evaporator chamber 410. In the illustrated example, a first channel 504a of the housing 302 fluidly couples a first condenser area 506a and/or the wicking material 414 and the first housing outlet 310a, and a second channel 504b of the housing 302 fluidly couples a second condenser area 506b and/or the wicking material 414 and the second housing outlet 310b. To this end, a first portion 502a of the primary flow path 502 (e.g., a left side of the housing 302 in the orientation of FIG. 5) is fluidly coupled to the first housing outlet 310a and a second portion 502b of the primary flow path 502 (e.g., a right side of the housing 302 in the orientation of FIG. 5) is fluidly coupled to the second housing outlet 310b. As a result, the first portion 502a of the primary flow path 502 (e.g., a left side of the housing 302 in the orientation of FIG. 5) fluidly couples the first condenser area 506a and the evaporator area 402 and/or the first housing outlet 310a and a second portion 502b of the primary flow path 502 (e.g., a right side of the housing 302 in the orientation of FIG. 5) fluidly couples the second condenser area 506b and the evaporator area 402 and/or the second housing outlet 310b.

To enable condensed heat transfer medium to bypass at least a portion of the primary flow path 502 via the pump 316 to increase a flow rate of the condensed working fluid at the housing inlet 312, the heat dissipation system 202 of the illustrated example includes a bypass flow path 508 (e.g., a secondary flow path). The bypass flow path 508 of the illustrated example is schematically represented by a double dot-dash line in FIG. 5. The bypass flow path 508 at least partially positioned in the housing 302 and at least partially positioned external to the housing 302.

For example, the bypass flow path 508 is fluidly coupled to the evaporator chamber 410 via the pump 316 (e.g., and the fluid reservoir 330). The bypass flow path 508 includes one or more pipes 510 external to the vapor chamber 208 defining the fluid lines 324-328. The bypass flow path 508 is a dynamic return channel or line provided by the wicking material 414 and the pipes 510 (e.g., external pipes). Specifically, the bypass flow path 508 of the illustrated example includes the pipes 510 defining the first fluid line 324, the second fluid line 326 and the third fluid line 328. Specifically, the pump 316 and the fluid reservoir 330 of the illustrated example are fluidly coupled to the vapor chamber 208. In particular, the pump outlet 318 is fluidly coupled to the housing inlet 312 via the first fluid line 324, the first housing outlet 310a is coupled to the first pump inlet 320 via the second fluid line 326, and the second housing outlet 310b is coupled to the second pump inlet 322 via the third fluid line 328. Thus, condensed liquid flows from the first housing outlet 310a and/or the second housing outlet 310b, to the pump 316, to the housing inlet 312 and to the evaporator chamber 410 (e.g., an evaporator surface) of the vapor chamber 208.

Although the bypass flow path 508 is external to the vapor chamber 208, the bypass flow path 508 is sealed from leakage. For example, the pipes 510 of the illustrated example are brazed and/or welded to the housing 302 of the vapor chamber 208. Additionally, epoxy 512 is provided at joints, couplings and/or interfaces between the fluid reservoir 330 and/or the pump 316 and the pipes 510. For example, the housing inlet 312, the first housing outlet 310a and the second housing outlet 310b can be openings and/or include flanges for receiving respective ends of the pipes 510.

In general, heat generated from the electronic and/or hardware components 200 and/or the CPU 206 is removed via the vapor chamber 208. For example, the electronic and/or hardware components 200 and/or the CPU 206 generate heat during operation that rises and/or transfers to the housing 302 (e.g., the evaporator area 402) of the vapor chamber 208. The heat transport medium, in a first or liquid phase, at the housing inlet 312 and/or within the evaporator chamber 410 removes or dissipates heat from the evaporator area 402, which causes the heat transfer medium to increase in temperature, thereby causing the heat transfer medium to evaporate from the liquid phase to a vapor phase. The heat transfer medium evaporates within the evaporator chamber 410 moves or spreads (e.g., rises) toward the condenser area 404.

To cool the heat transfer medium of the vapor chamber 208 after removing heat from the evaporator area 402 and/or the CPU 206, the heat dissipation system 202 of the illustrated example employs the heat exchangers 212 (FIGS. 2 and 3). For example, the heat exchangers 212 are heat fins or radiators that remove heat from the vapor (e.g., the heat transfer medium in the second phase) via a cooling fluid (e.g., fan air provided by the fans 132). For example, the cooling fluid of the illustrated example is provided by fan air that is drawn through the heat exchangers 212 to cool or remove heat from the vapor or heat transfer medium in the condenser area 404. In some examples, the heat exchanger 212 provides means for cooling or removing heat from the heat transfer medium. At the condenser area 404, one or more fans 132 can be employed to provide cooler airflow to remove the heat from the vapor. In turn, the vapor reduces in temperature to cause the vapor to condense to liquid at the condenser area 404. The wicking material 414 absorbs the condensation and transports condensed liquid toward the housing inlet 312 and/or the evaporator chamber 410 via capillary action via the primary flow path 502. The wicking material 414 extends from the condenser area 404 to the evaporator area 402 and is fluidly coupled to the fluid reservoir 330 and the pump 316.

The pump 316 draws the condensed liquid or heat transfer medium from the first housing outlet 310a and the second housing outlet 310b and increases a pressure and/or flow rate of the heat transfer medium at the housing inlet 312. For example, the pump 316 of the illustrated example draws heat transfer medium (e.g., condensed liquid) from the first housing outlet 310a (e.g., the wicking material 414) via the bypass flow path 508 (e.g., the first bypass portion 508a and the second fluid line 326) and draws heat transfer medium (e.g., condensed liquid) from the second housing outlet 310b (e.g., the wicking material 414) via the bypass flow path 508 (e.g., the second bypass portion 508b and the third fluid line 328). The pump 315 increases the flow rate and/or pressure of the heat transfer medium and delivers the fluid to the housing inlet 312 via the first fluid line 324. Thus, the pump 316 supplements and/or increases a flow rate of the fluid provided by the capillary action of the wicking material 414.

The heat dissipation system 202 and/or the pump 316 of the illustrated example can operate in different modes or phases (e.g., active mode, passive mode, a first frequency mode, a second frequency mode, etc.) based on a workload or detected condition of the electronic device 100. In some examples, the heat dissipation system 202 and/or the pump 316 operate in a first mode or an active mode (e.g., an active phase of heat dissipation) in response to the detected condition exceeding a condition threshold and a second mode or deactivated mode (e.g., a passive phase of heat dissipation) in response to the detected condition not exceeding the condition threshold. The detected condition(s) can be based on one or more of a power output of one or more electronic and/or hardware components 200, a fan speed of the fans 132, a temperature of one or more electronic and/or hardware components 200, a skin temperature of a skin enclosure, and/or any other conditions, and/or operating parameters of an electronic device 100. For example, when a workload of an electronic device 100 increases and more heat transfer capability is needed, the pump 316 can be activated and/or can operate at a higher frequency (e.g., the first mode) to increase a flow rate of the heat transfer medium. In contrast, when a workload of the electronic device 100 decreases, the pump 316 can be deactivated and/or operate at a lower frequency (e.g., a second mode) to reduce or decrease a flow rate of the heat transfer medium. In such examples, excess heat transfer medium can be stored in the fluid reservoir 330.

In some examples, the heat dissipation system 202 and/or the pump 316 operate in a first mode or a second mode. In the first mode of operation, the pump 316 operates at a first operational mode (e.g., a first frequency). In the second mode of operation, the pump 316 operates a second operational mode (e.g., a second frequency) different than the first operational mode. For example, the pump 316 can operate in the first mode to increase a flow rate of the working fluid through the vapor chamber 208 in response to a detected condition exceeding a condition threshold and operate in the second mode in response to the detected condition not exceeding the condition threshold. For example, the pump 316 can operate at a higher frequency in the first mode to provide higher flow rate requirements (e.g., Qmax) to drive more liquid into the vapor chamber 208. In such examples, the pump 316 can draw liquid or heat transfer medium from the fluid reservoir 330. In some examples, the pump 316 can operate at a lower frequency in the second mode to provide lower flow rate requirements (Qmin) when a workload or power requirement of the electronic device is low. In such examples, excess heat transfer medium or liquid can be stored in the fluid reservoir 330.

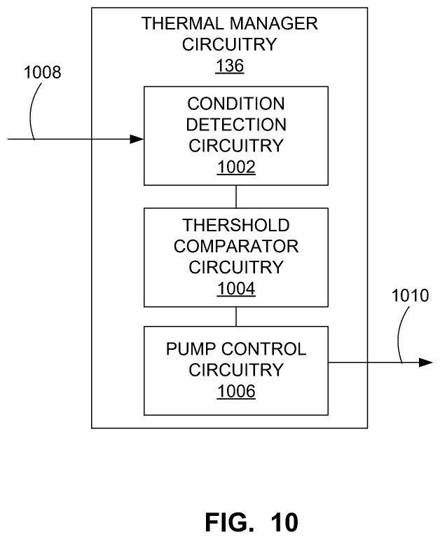

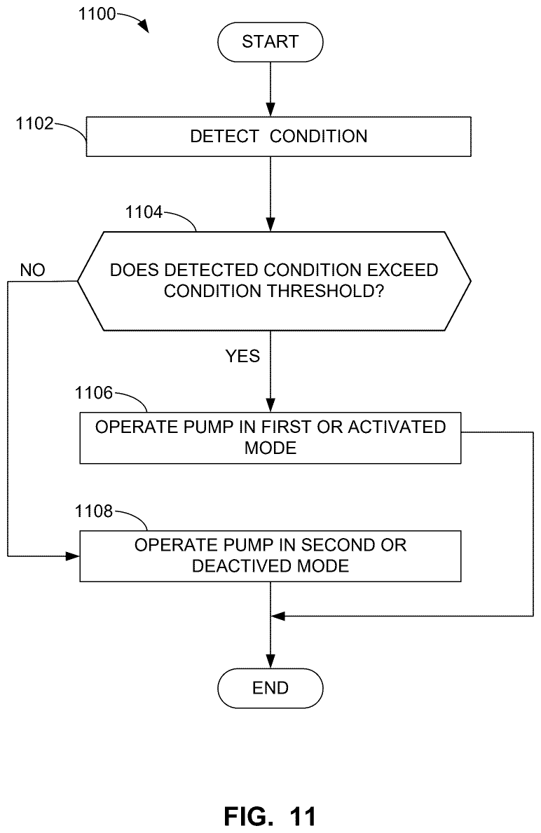

In some examples, to remove heat from the components, the vapor chamber of the illustrated example can operate in a passive mode or an active mode (e.g., based on one or more detected conditions). Specifically, in the passive mode, the heat dissipation system 202 and/or the vapor chamber 208 operates without the pump 316. In other words, the pump 316 is in a deactivated state and the vapor chamber 208 operates to remove heat from the components. In the passive mode, the wicking material 414 circulates the heat transfer medium in the vapor chamber 208 via capillary action (e.g., without any external assistance from the pump 316). For example, in the passive mode, the primary flow path 502 and/or the wicking material 414 passively moves the working fluid between the condenser area 404 and the evaporator area 402 without input from the pump 316. In the active mode, the pump 316 is activated to increase flow rate of the heat transfer medium through the wicking material 414. Additionally, in the active mode, the pump 316 can deliver and/or increase a volume of the heat transfer medium from the fluid reservoir 330 to the vapor chamber 208. Further examples of operating the pump 316 and/or the heat dissipation system 202 is provided below in connection with FIGS. 10 and 11.

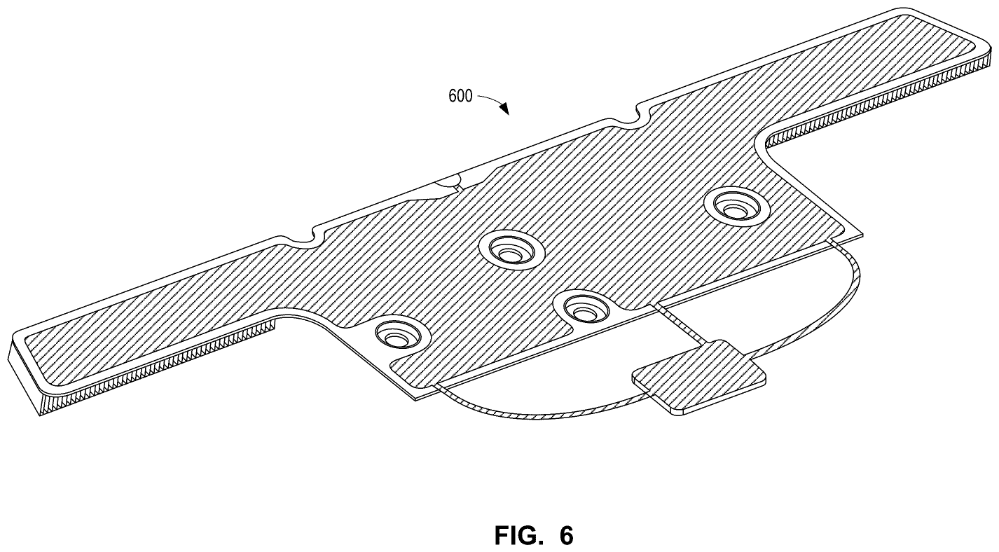

FIGS. 6-9 illustrate other example vapor chambers 600-900 disclosed herein. Many of the components of the example vapor chambers 600-900 of FIGS. 6-9 are substantially similar or identical to the components described above in connection with FIGS. 1-5. As such, those components will not be described in detail again below. Instead, the interested reader is referred to the above corresponding descriptions for a complete written description of the structure and operation of such components. To facilitate this process, similar or identical reference numbers will be used for like structures in FIGS. 6-9 as used in FIGS. 1-5. The vapor chambers 600-900 of FIGS. 6-9 illustrate various vapor chambers 600-900 that may be used to implement the heat dissipation system 102 and/or the vapor chamber 208 of FIGS. 1-5.

FIG. 6 is a top view of an example heat dissipation system 600 disclosed herein. The heat dissipation system 600 of FIG. 6 is substantially the same or identical to the heat dissipation system 202 of FIGS. 2-5, except that heat dissipation system 600 does not include a fluid reservoir (e.g., the fluid reservoir 330 of FIG. 3).

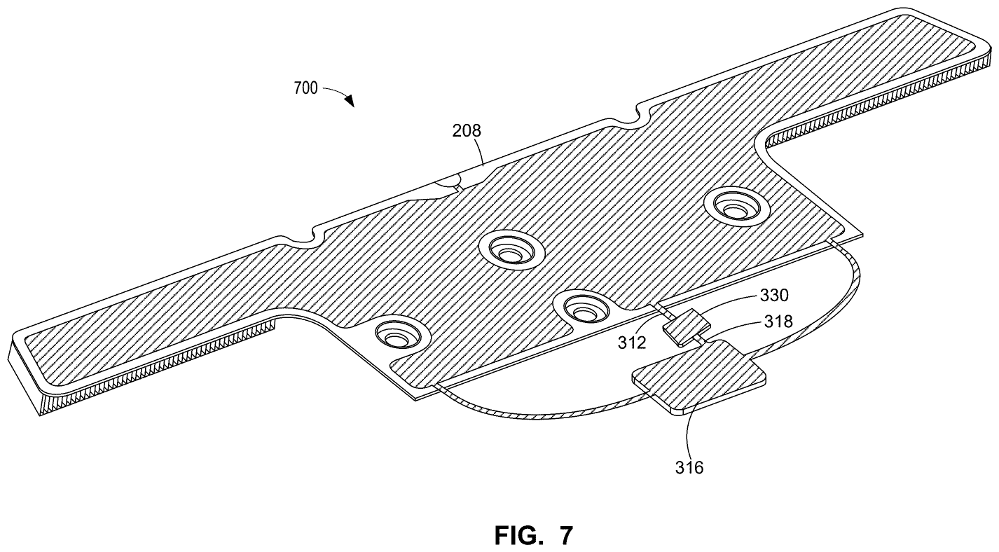

FIG. 7 is a top view of an example heat dissipation system 700 disclosed herein. The heat dissipation system 700 of FIG. 7 is substantially the same or identical to the heat dissipation system 202 of FIGS. 2-5, except that a fluid reservoir 330 is positioned downstream from a pump 316. In other words, the fluid reservoir 330 is positioned between a housing inlet 312 of a vapor chamber 208 and a pump outlet 318.

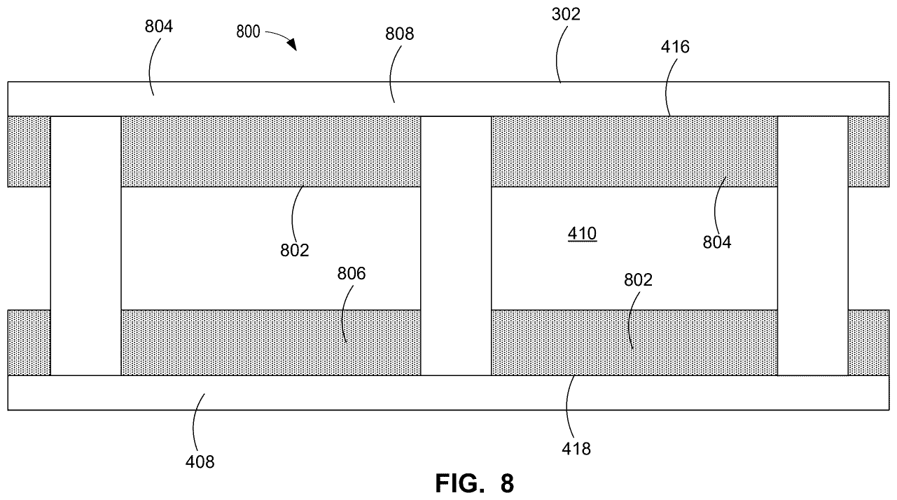

FIG. 8 is a cross-sectional view of an example heat dissipation system 800 disclosed herein. The heat dissipation system 800 of FIG. 8 is substantially the same or identical to the heat dissipation system 202 of FIGS. 2-5, except that a vapor chamber 808 of the heat dissipation system 800 includes a wick structure 802 different than the wicking material 414 of FIGS. 2-5. For example, the wick structure 802 of the illustrated example extends across substantially an entirety of the evaporator chamber 410 of the vapor chamber 808. For example, the wick structure 802 of the illustrated example has a first wick 804 positioned on an inner surface 416 of a first plate 406 of a housing 302 and a second wick 806 positioned on an inner surface 418 of the second plate 408 of the housing 302. The wick structure 802 does not provide a gap across the evaporator chamber 410.

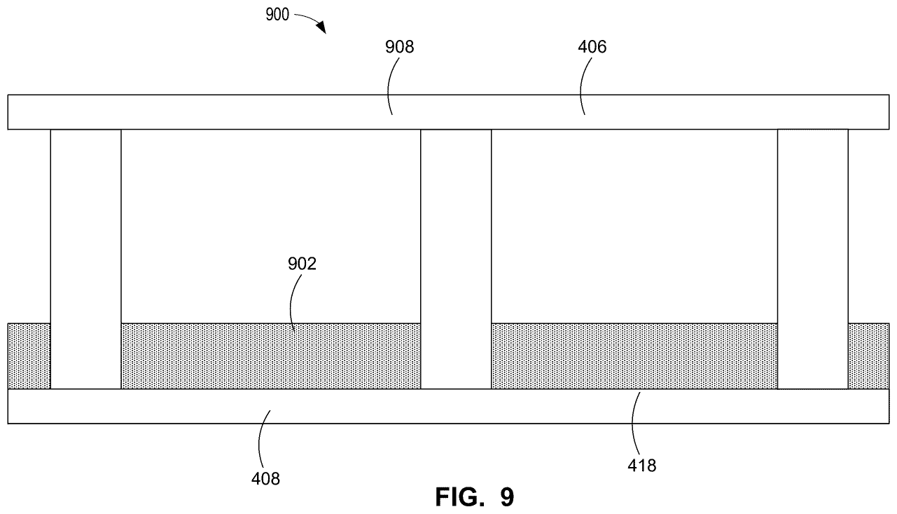

FIG. 9 is a cross-sectional view of an example heat dissipation system 900 disclosed herein. The heat dissipation system 900 of FIG. 9 is substantially the same or identical to the heat dissipation system 800 of FIG. 8, except that a wick structure 902 of an example vapor chamber 908 is provided only on the second plate 408. In other words, the first plate 406 does not have a wick structure (e.g., a first wick 414a, 804).

Although each example heat dissipation systems 102, 202, 600-900 disclosed above have certain features, it should be understood that it is not necessary for a particular feature of one example to be used exclusively with that example. Instead, any of the features described above and/or depicted in the drawings can be combined with any of the examples, in addition to or in substitution for any of the other features of those examples. One example's features are not mutually exclusive to another example's features. Instead, the scope of this disclosure encompasses any combination of any of the features.

FIG. 10 is a block diagram of an example implementation of example thermal manager circuitry 136 (e.g., thermal manager circuitry) that can implement the heat dissipation systems 102, 202, and 600-900 disclosed herein (e.g., to operate the pump 316). The thermal manager circuitry 136 of FIG. 10 may be instantiated (e.g., creating an instance of, bring into being for any length of time, materialize, implement, etc.) by programmable circuitry such as a Central Processor Unit (CPU) executing first instructions. Additionally or alternatively, the thermal manger circuitry 136 of FIG. 10 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 10 may, thus, be instantiated at the same or different times. Some or all of the circuitry of FIG. 10 may be instantiated, for example, in one or more threads executing concurrently on hardware and/or in series on hardware. Moreover, in some examples, some or all of the circuitry of FIG. 10 may be implemented by microprocessor circuitry executing instructions and/or FPGA circuitry performing operations to implement one or more virtual machines and/or containers.

The example thermal manager circuitry 136 includes an example condition determination circuitry 1002, an example threshold comparator circuitry 1004, and an example pump control circuitry 1006. In some examples, the example condition determination circuitry 1002, the example threshold comparator circuitry 1004, and the example pump control circuitry 1006 are in communication (e.g., via a communication bus, by writing and reading data from a memory, etc.). The thermal manager circuitry 136 operates the pump 316 in a passive phase of heat dissipation and operates the pump 316 in an active phase of heat dissipation based on a detected condition of the electronic device 100.

The condition determination circuitry 1002 determines an operating condition of the electronic device 100. For example, the condition determination circuitry 1002 can receive one or more signals 1008 (e.g., feedback signals) representative of one or more conditions of the electronic device 100. For example, the condition determination circuitry 1002 can receive signals 1008 from the temperature sensor(s) 134, a fan speed from a fan module of the fan 132, a power output of the CPU 206, information provided by application programming interface(s) API, and/or any other parameter(s) of the electronic device 100. In some examples, the condition determination circuitry 1002 of the illustrated example determines a power output of one or more electronic and/or hardware components 200, a fan speed of the fans 132, a temperature of one or more electronic and/or hardware components 200, a skin temperature of a skin enclosure, and/or any other conditions, and/or operating parameters of an electronic device 100. In some examples, the condition determination circuitry 1002 employs an application programming interface (API) to provide a power output of one or more of the electronic and/or hardware components 200 (e.g., the CPU 206), fan speed of the fans 132, and/or any other condition or operating parameter of the electronic device 100.

The threshold comparator circuitry 1004 of the illustrated example compares the detected operating condition provided by the condition determination circuitry 1002 to a condition threshold. For example, the threshold comparator circuitry 1004 obtains or retrieves a condition threshold value from memory or a look-up table. The condition threshold values can include, for example, a power threshold, a temperature threshold, a fan speed threshold, a skin temperature threshold and/or any other threshold. For example, the threshold comparator circuitry 1004 can provide a first signal (e.g., a binary value of “1”) to the pump control circuitry 1006 in response to determining that the detected condition exceeds the condition threshold and a second signal (e.g., a binary value “0”) different than the first signal to the pump control circuitry 1006 in response to determining that the detected condition does not exceed the condition threshold.

The example pump control circuitry 1006 operates the example pump 316 based on a detected condition provided by the condition determination circuitry 1002 and the comparison of the detected condition to a condition threshold provided by the threshold comparator circuitry 1004. To control operation of the pump 316, the pump control circuitry 1006 of the illustrated example sends one or more instructions and/or commands 1010 (e.g., electrical signals, binary signals, analog signals, current, etc.) to the pump 316. The example pump control circuitry 1006 may activate the pump 316 based on one or more detected conditions determined by one or more of the example condition determination circuitry 1002 and/or the threshold comparator circuitry 1004.

The pump control circuitry 1006 can operate the pump 316 to operate between an activated (e.g., an active phase of heat dissipation) or deactivated/passive mode or phase (e.g., a passive phase of heat dissipation). Additionally or alternatively, the pump control circuitry 1006 of the illustrated example can operate the pump 316 between a first mode (e.g., a first or higher frequency mode, an active phase of heat dissipation) or a second mode (e.g., a second or lower frequency mode, a passive phase of heat dissipation). In the first mode (e.g., a higher frequency mode) and/or the active mode (e.g., an increased pressure condition), the pump 316 provides a higher flow rate (e.g., Qmax, drive more liquid) into the vapor chamber 208 (e.g., the evaporator chamber 410 and/or wicking material 414). In the first mode and/or the active mode, additional heat transfer medium can be drawn from the fluid reservoir 330.

In the second mode, the pump 316 provides a lower flow rate (e.g., Qmin, or Q less than Qmax) to the vapor chamber 208 (e.g., the evaporator chamber 410 and/or the wicking material 414). In the deactivated mode, the pump control circuitry 1006 causes the pump 316 to shut off. In the shut-off position, the pump 316 does not provide heat transfer medium to the housing inlet 312 of the housing 302. When the pump 316 is turned off, the vapor chamber 208 operates in a passive mode (e.g., without the assistance of the pump 316). When the pump 316 operates in the second mode (e.g., a lower frequency mode) and/or deactivated mode, excess heat transfer medium or liquid can be stored in the fluid reservoir 330.

In some examples, the thermal manager circuitry 136 (FIG. 1) operates the heat dissipation system 102, 202, 600-900 between a first mode or activated mode and a second mode or deactivated mode based on a power output of one or more electronic or hardware components 200 and/or the CPU 206 of the electronic device 100 determined by the condition determination circuitry 1002. For example, when the threshold comparator circuitry 1004 determines that a power output of the electronic device 100 and the CPU 206 detected by the condition determination circuitry 1002 exceeds a power threshold (e.g., 10 Watts), the pump control circuitry 1006 causes the pump 316 to operate at a first mode (e.g., a higher frequency mode) and/or an active mode (e.g., an increased pressure condition) to provide a higher flow rate (e.g., Qmax, drive more liquid) into the evaporator chamber 410 and/or wicking material 414. Additional heat transfer medium can be drawn from the fluid reservoir 330 when the pump 316 operates in the first mode (e.g., a higher frequency mode). In contrast, when the condition determination circuitry 1002 and the threshold comparator circuitry 1004 determine that a power output of the electronic device 100 and/or CPU 206 does not exceed a power threshold, the pump control circuitry 1006 can cause the pump 316 to operate at a second mode (e.g., low frequency mode) to reduce a flow rate through the vapor chamber 208 or a deactivated mode (e.g., turned-off or removed external pressure condition) to enable the vapor chamber 208 to operate in a passive mode.

In some examples, the thermal manager circuitry 136 can operate the heat dissipation system 102, 202, 600-900 between the first mode/second mode or the active mode/deactivated mode based a fan speed of the fan 132. For instance, the condition determination circuitry 1002 can receive one or more signals from a rotary encoder, an API and/or other sensor(s) or program(s) providing a fan speed of the fans 132. For example, the pump control circuitry 1006 can cause the pump 316 to operate in the first mode (e.g., a high frequency mode) or the active mode when the condition determination circuitry 1002 and the threshold comparator circuitry 1004 determine that the fan speed exceeds a fan speed threshold. In contrast, the pump control circuitry 1006 can cause the pump 316 to operate in the second mode (e.g., a low frequency mode) or the deactivated mode when the condition determination circuitry 1002 and the threshold comparator circuitry 1004 determine that the fan speed does not exceed a fan speed threshold.

In some examples, the thermal manager circuitry 136 can operate the heat dissipation system 102, 202, 600-900 in the first mode/second mode or the activated/deactivated mode when a temperature of one or more of the electronic and/or hardware components (e.g., the CPU 206) exceeds the temperature threshold. For instance, the condition determination circuitry 1002 can receive one or more temperature feedback signals (e.g., the signals 1008) from the temperature sensor(s) 134. The pump control circuitry 10065 can cause the pump 316 to operate in the first mode or active mode in response to the condition determination circuitry 1002 and the threshold comparator circuitry 1004 determining that the detected temperature exceeds the temperature threshold. In contrast, the pump control circuitry 1006 can operate the pump 316 in the second mode or the deactivated mode in response to the threshold comparator circuitry 1004 determining that the detected temperature does not exceed a temperature threshold.

In some examples, the thermal manager circuitry 136 can operate the heat dissipation system 102, 202, 600-900 between the first mode or the active mode and the second mode or the passive mode based on a skin enclosure temperature(s). In some examples, the condition determination circuitry 1002 can receive feedback signals from one or more sensors providing a skin temperature of the first housing 104 and/or the second housing 106. For instance, the pump control circuitry 1006 can cause the pump 316 to operate in the first mode or the active mode in response to the condition determination circuitry 1002 and the threshold comparator circuitry 1004 detecting that a skin temperature of the first housing 104 and/or the second housing 106 exceeds a skin temperature threshold. In contrast, the pump control circuitry 1006 can cause the pump 316 to operate in the second mode or the deactivated mode in response to the condition determination circuitry 1002 and the threshold comparator circuitry 1004 detecting that a skin temperature of the first housing 104 and/or the second housing 106 does not exceed a skin temperature threshold.

In some examples, the condition determination circuitry 1002 is instantiated by programmable circuitry executing condition determining circuitry instructions and/or configured to perform operations such as those represented by the flowchart of FIG. 11

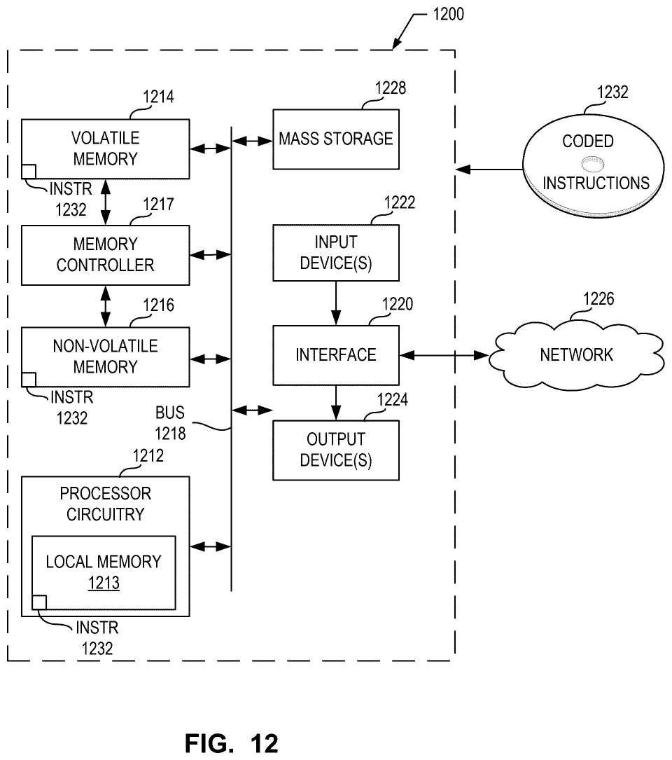

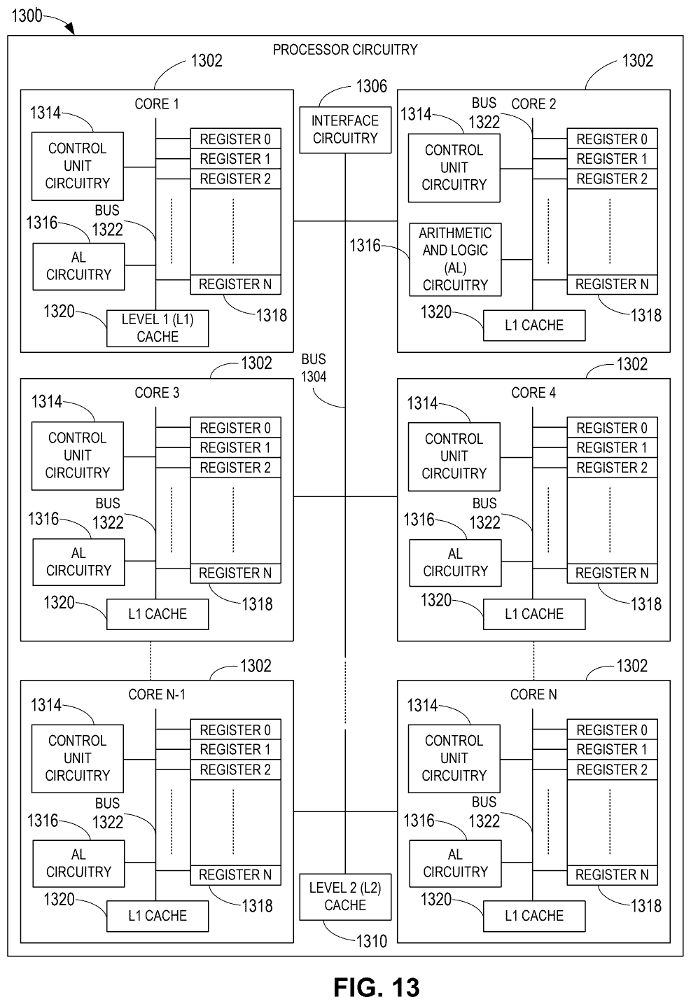

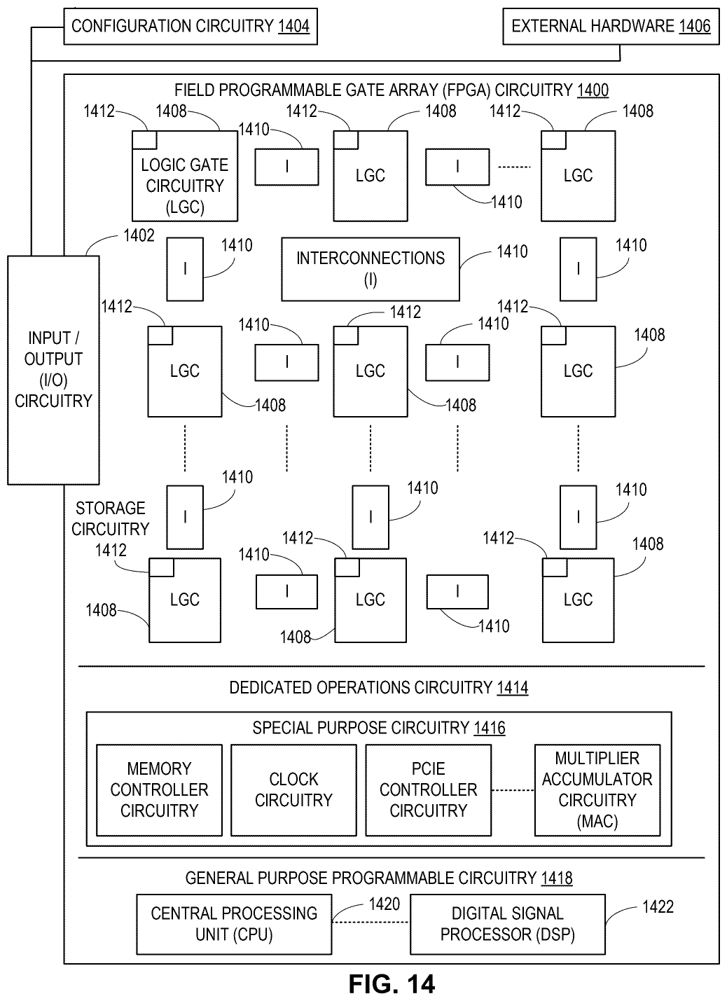

In some examples, the thermal manager circuitry 136 includes means for determining a condition of an electronic device. For example, the means for determining may be implemented by condition determination circuitry 1002. In some examples, the condition determination circuitry 1002 may be instantiated by programmable circuitry such as the example programmable circuitry 1212 of FIG. 12. For instance, the condition determination circuitry 1002 may be instantiated by the example microprocessor 1300 of FIG. 13 executing machine executable instructions such as those implemented by at least block 1102 of FIG. 11. In some examples, the condition determination circuitry 1002 may be instantiated by hardware logic circuitry, which may be implemented by an ASIC, XPU, or the FPGA circuitry 1400 of FIG. 14 configured and/or structured to perform operations corresponding to the machine readable instructions. Additionally or alternatively, the condition determination circuitry 1002 may be instantiated by any other combination of hardware, software, and/or firmware. For example, the condition determination circuitry 1002 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the threshold comparator circuitry 1004 is instantiated by programmable circuitry executing condition determining circuitry instructions and/or configured to perform operations such as those represented by the flowchart of FIG. 11.

In some examples, the thermal manager circuitry 136 includes means for determining if a detected condition of an electronic device exceeds a condition threshold. For example, the means for determining may be implemented by condition comparator circuitry 1004. In some examples, the threshold comparator circuitry 1004 may be instantiated by programmable circuitry such as the example programmable circuitry [1212 of FIG. 12. For instance, the threshold comparator circuitry 1004 may be instantiated by the example microprocessor 1300 of FIG. 13 executing machine executable instructions such as those implemented by at least block 1104 of FIG. 11. In some examples, the threshold comparator circuitry 1004 may be instantiated by hardware logic circuitry, which may be implemented by an ASIC, XPU, or the FPGA circuitry 1400 of FIG. 14 configured and/or structured to perform operations corresponding to the machine readable instructions. Additionally or alternatively, the threshold comparator circuitry 1004 may be instantiated by any other combination of hardware, software, and/or firmware. For example, the threshold comparator circuitry 1004 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the pump control circuitry 1006 is instantiated by programmable circuitry executing condition determining circuitry instructions and/or configured to perform operations such as those represented by the flowchart of FIG. 11.

In some examples, the thermal manager circuitry 136 includes means for controlling an operation of a pump. For example, the means for determining may be implemented by pump control circuitry 1006. In some examples, the pump control circuitry 1006 may be instantiated by programmable circuitry such as the example programmable circuitry [1212 of FIG. 12. For instance, the pump control circuitry 1006 may be instantiated by the example microprocessor 1300 of FIG. 13 executing machine executable instructions such as those implemented by at least block 1102 of FIG. 11. In some examples, the pump control circuitry 1006 may be instantiated by hardware logic circuitry, which may be implemented by an ASIC, XPU, or the FPGA circuitry 1400 of FIG. 14 configured and/or structured to perform operations corresponding to the machine readable instructions. Additionally or alternatively, the pump control circuitry 1006 may be instantiated by any other combination of hardware, software, and/or firmware. For example, the pump control circuitry 1006 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

While an example manner of implementing the thermal manager circuitry 136 of FIG. 10 is illustrated in FIG. 10, one or more of the elements, processes, and/or devices illustrated in FIG. 10 may be combined, divided, re-arranged, omitted, eliminated, and/or implemented in any other way. Further, the condition determination circuitry 1002, the threshold comparator circuitry 1004, the pump control circuitry 1006 and/or, more generally, the example thermal manager circuitry of FIG. 10, may be implemented by hardware alone or by hardware in combination with software and/or firmware. Thus, for example, any of the condition determination circuitry 1002, the threshold comparator circuitry 1004, the pump control circuitry 1006 and/or, more generally, the example thermal manager circuitry of FIG. 10, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example thermal manager circuitry 136 of FIG. 10 may include one or more elements, processes, and/or devices in addition to, or instead of, those illustrated in FIG. 10, and/or may include more than one of any or all of the illustrated elements, processes, and devices.

A flowchart representative of example machine readable instructions, which may be executed by programmable circuitry to implement and/or instantiate the thermal manager circuitry 136 of FIG. 10 and/or representative of example operations which may be performed by programmable circuitry to implement and/or instantiate the thermal manager circuitry 136 of FIG. 10, are shown in FIG. 11. The machine readable instructions may be one or more executable programs or portion(s) of one or more executable programs for execution by programmable circuitry such as the programmable circuitry 1212 shown in the example processor platform 1200 discussed below in connection with FIG. 12 and/or may be one or more function(s) or portion(s) of functions to be performed by the example programmable circuitry (e.g., an FPGA) discussed below in connection with FIGS. 13 and/or 14. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIG. 11, many other methods of implementing the example thermal manager circuitry 136 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 11 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

FIG. 11 is a flowchart representative of example machine readable instructions and/or example operations 1100 that may be executed, instantiated, and/or performed by programmable circuitry to implement the example thermal manager circuitry 136 of FIG. 10 to operate the heat dissipation systems 102, 202, and 600-900 and/or the pump 316 disclosed herein. The example machine-readable instructions and/or the example operations 1100 of FIG. 11 begin at block 1102, at which the condition determination circuitry 1002 detects a condition of the electronic device 100. In some examples, the condition determination circuitry 1002 receives one or more feedback signals from a temperature sensor, a speed sensor, an API, a system of the electronic device 100 and/or any other feedback signal and/or information.

At block 1104, the threshold comparator circuitry 1004 compares the detected condition to a condition threshold to determine if the detected condition provided by the condition determination circuitry 1002 exceeds the condition threshold. For example, in response to the threshold comparator circuitry 1004 determining that the detected condition exceeds the condition threshold (e.g., “YES”), control advances to block 1106. Alternatively, in response to the threshold comparator circuitry 1004 determining that the detected condition does not exceed the condition threshold (e.g., “NO”), control advances to block 1108.

At block 1106, the pump control circuitry 1006 causes the heat dissipation system 102, 202 or 600-900 and/or the pump 316 to operate in a first mode or activated mode. For example, the thermal control circuitry 136 operates the pump 316 and/or the vapor chamber 208 (or 608-908) in an active phase of heat dissipation in the first mode and/or the active mode. At block 1108, the pump control circuitry 1006 causes the heat dissipation system 102, 202 or 600-900 and/or the pump 316 to operate in a second mode or deactivated mode. For instance, the thermal control circuitry 136 operates the pump 316 and/or the vapor chamber 208 (or 608-908) in a passive phase of heat dissipation in the second mode and/or the deactivated mode.

FIG. 12 is a block diagram of an example programmable circuitry platform 1200 structured to execute and/or instantiate the example machine-readable instructions and/or the example operations of FIG. 11 to implement the thermal manager circuitry 136 of FIG. 12. The programmable circuitry platform 1200 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 1200 of the illustrated example includes programmable circuitry 1212. The programmable circuitry 1212 of the illustrated example is hardware. For example, the programmable circuitry 1212 can be implemented by one or more integrated circuits, logic circuits, FPGAs, microprocessors, CPUs, GPUs, DSPs, and/or microcontrollers from any desired family or manufacturer. The programmable circuitry 1212 may be implemented by one or more semiconductor based (e.g., silicon based) devices. In this example, the programmable circuitry 1212 implements the condition determination circuitry 1002, the threshold comparator circuitry 1004 and the pump control circuitry 1006.

The programmable circuitry 1212 of the illustrated example includes a local memory 1213 (e.g., a cache, registers, etc.). The programmable circuitry 1212 of the illustrated example is in communication with main memory 1214, 1216, which includes a volatile memory 1214 and a non-volatile memory 1216, by a bus 1218. The volatile memory 1214 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1216 may be implemented by flash memory and/or any other desired type of memory device. Access to the main memory 1214, 1216 of the illustrated example is controlled by a memory controller 1217. In some examples, the memory controller 1217 may be implemented by one or more integrated circuits, logic circuits, microcontrollers from any desired family or manufacturer, or any other type of circuitry to manage the flow of data going to and from the main memory 1214, 1216.

The programmable circuitry platform 1200 of the illustrated example also includes interface circuitry 1220. The interface circuitry 1220 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 1222 are connected to the interface circuitry 1220. The input device(s) 1222 permit(s) a user (e.g., a human user, a machine user, etc.) to enter data and/or commands into the programmable circuitry 1212. The input device(s) 1222 can be implemented by, for example, an audio sensor, a microphone, a camera (still or video), a keyboard, a button, a mouse, a touchscreen, a trackpad, a trackball, an isopoint device, and/or a voice recognition system.

One or more output devices 1224 are also connected to the interface circuitry 1220 of the illustrated example. The output device(s) 1224 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1220 of the illustrated example, thus, typically includes a graphics driver card, a graphics driver chip, and/or graphics processor circuitry such as a GPU.

The interface circuitry 1220 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1226. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1200 of the illustrated example also includes one or more mass storage discs or devices 1228 to store firmware, software, and/or data. Examples of such mass storage discs or devices 1228 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 1232, which may be implemented by the machine readable instructions of FIG. 11, may be stored in the mass storage device 1228, in the volatile memory 1214, in the non-volatile memory 1216, and/or on at least one non-transitory computer readable storage medium such as a CD or DVD which may be removable.

FIG. 13 is a block diagram of an example implementation of the programmable circuitry 1212 of FIG. 12. In this example, the programmable circuitry 1212 of FIG. 12 is implemented by a microprocessor 1300. For example, the microprocessor 1300 may be a general-purpose microprocessor (e.g., general-purpose microprocessor circuitry). The microprocessor 1300 executes some or all of the machine-readable instructions of the flowchart of FIG. 11to effectively instantiate the circuitry of FIG. 2 as logic circuits to perform operations corresponding to those machine readable instructions. In some such examples, the circuitry of FIG. 12 is instantiated by the hardware circuits of the microprocessor 1300 in combination with the machine-readable instructions. For example, the microprocessor 1300 may be implemented by multi-core hardware circuitry such as a CPU, a DSP, a GPU, an XPU, etc. Although it may include any number of example cores 1302 (e.g., 1 core), the microprocessor 1300 of this example is a multi-core semiconductor device including N cores. The cores 1302 of the microprocessor 1300 may operate independently or may cooperate to execute machine readable instructions. For example, machine code corresponding to a firmware program, an embedded software program, or a software program may be executed by one of the cores 1302 or may be executed by multiple ones of the cores 1302 at the same or different times. In some examples, the machine code corresponding to the firmware program, the embedded software program, or the software program is split into threads and executed in parallel by two or more of the cores 1302. The software program may correspond to a portion or all of the machine readable instructions and/or operations represented by the flowchart of FIG. 11.

The cores 1302 may communicate by a first example bus 1304. In some examples, the first bus 1304 may be implemented by a communication bus to effectuate communication associated with one(s) of the cores 1302. For example, the first bus 1304 may be implemented by at least one of an Inter-Integrated Circuit (I2C) bus, a Serial Peripheral Interface (SPI) bus, a PCI bus, or a PCIe bus. Additionally or alternatively, the first bus 1304 may be implemented by any other type of computing or electrical bus. The cores 1302 may obtain data, instructions, and/or signals from one or more external devices by example interface circuitry 1306. The cores 1302 may output data, instructions, and/or signals to the one or more external devices by the interface circuitry 1306. Although the cores 1302 of this example include example local memory 1320 (e.g., Level 1 (L1) cache that may be split into an L1 data cache and an L1 instruction cache), the microprocessor 1300 also includes example shared memory 1310 that may be shared by the cores (e.g., Level 2 (L2 cache)) for high-speed access to data and/or instructions. Data and/or instructions may be transferred (e.g., shared) by writing to and/or reading from the shared memory 1310. The local memory 1320 of each of the cores 1302 and the shared memory 1310 may be part of a hierarchy of storage devices including multiple levels of cache memory and the main memory (e.g., the main memory 1214, 1216 of FIG. 12). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1302 may be referred to as a CPU, DSP, GPU, etc., or any other type of hardware circuitry. Each core 1302 includes control unit circuitry 1314, arithmetic and logic (AL) circuitry (sometimes referred to as an ALU) 1316, a plurality of registers 1318, the local memory 1320, and a second example bus 1322. Other structures may be present. For example, each core 1302 may include vector unit circuitry, single instruction multiple data (SIMD) unit circuitry, load/store unit (LSU) circuitry, branch/jump unit circuitry, floating-point unit (FPU) circuitry, etc. The control unit circuitry 1314 includes semiconductor-based circuits structured to control (e.g., coordinate) data movement within the corresponding core 1302. The AL circuitry 1316 includes semiconductor-based circuits structured to perform one or more mathematic and/or logic operations on the data within the corresponding core 1302. The AL circuitry 1316 of some examples performs integer based operations. In other examples, the AL circuitry 1316 also performs floating-point operations. In yet other examples, the AL circuitry 1316 may include first AL circuitry that performs integer-based operations and second AL circuitry that performs floating-point operations. In some examples, the AL circuitry 1316 may be referred to as an Arithmetic Logic Unit (ALU).

The registers 1318 are semiconductor-based structures to store data and/or instructions such as results of one or more of the operations performed by the AL circuitry 1316 of the corresponding core 1302. For example, the registers 1318 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1318 may be arranged in a bank as shown in FIG. 13. Alternatively, the registers 1318 may be organized in any other arrangement, format, or structure, such as by being distributed throughout the core 1302 to shorten access time. The second bus 1322 may be implemented by at least one of an I2C bus, a SPI bus, a PCI bus, or a PCIe bus.

Each core 1302 and/or, more generally, the microprocessor 1300 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 1300 is a semiconductor device fabricated to include many transistors interconnected to implement the structures described above in one or more integrated circuits (ICs) contained in one or more packages.

The microprocessor 1300 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 1300, in the same chip package as the microprocessor 1300 and/or in one or more separate packages from the microprocessor 1300.

FIG. 14 is a block diagram of another example implementation of the programmable circuitry 1212 of FIG. 12. In this example, the programmable circuitry 1212 is implemented by FPGA circuitry 1400. For example, the FPGA circuitry 1400 may be implemented by an FPGA. The FPGA circuitry 1400 can be used, for example, to perform operations that could otherwise be performed by the example microprocessor 1300 of FIG. 13 executing corresponding machine readable instructions. However, once configured, the FPGA circuitry 1400 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 1300 of FIG. 13 described above (which is a general purpose device that may be programmed to execute some or all of the machine readable instructions represented by the flowchart(s) of FIG. 11but whose interconnections and logic circuitry are fixed once fabricated), the FPGA circuitry 1400 of the example of FIG. 14 includes interconnections and logic circuitry that may be configured, structured, programmed, and/or interconnected in different ways after fabrication to instantiate, for example, some or all of the operations/functions corresponding to the machine readable instructions represented by the flowchart(s) of FIG. 11. In particular, the FPGA circuitry 1400 may be thought of as an array of logic gates, interconnections, and switches. The switches can be programmed to change how the logic gates are interconnected by the interconnections, effectively forming one or more dedicated logic circuits (unless and until the FPGA circuitry 1400 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIG. 11. As such, the FPGA circuitry 1400 may be configured and/or structured to effectively instantiate some or all of the operations/functions corresponding to the machine readable instructions of the flowchart(s) of FIG. 11as dedicated logic circuits to perform the operations/functions corresponding to those software instructions in a dedicated manner analogous to an ASIC. Therefore, the FPGA circuitry 1400 may perform the operations/functions corresponding to the some or all of the machine readable instructions of FIG. 11faster than the general-purpose microprocessor can execute the same.

In the example of FIG. 14, the FPGA circuitry 1400 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1400 of FIG. 14 may access and/or load the binary file to cause the FPGA circuitry 1400 of FIG. 14 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1400 of FIG. 14 to cause configuration and/or structuring of the FPGA circuitry 1400 of FIG. 14, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 1400 of FIG. 14 may access and/or load the binary file to cause the FPGA circuitry 1400 of FIG. 14 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1400 of FIG. 14 to cause configuration and/or structuring of the FPGA circuitry 1400 of FIG. 14, or portion(s) thereof.

The FPGA circuitry 1400 of FIG. 14, includes example input/output (I/O) circuitry 1402 to obtain and/or output data to/from example configuration circuitry 1404 and/or external hardware 1406. For example, the configuration circuitry 1404 may be implemented by interface circuitry that may obtain a binary file, which may be implemented by a bit stream, data, and/or machine-readable instructions, to configure the FPGA circuitry 1400, or portion(s) thereof. In some such examples, the configuration circuitry 1404 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 1406 may be implemented by external hardware circuitry. For example, the external hardware 1406 may be implemented by the microprocessor 1300 of FIG. 13.

The FPGA circuitry 1400 also includes an array of example logic gate circuitry 1408, a plurality of example configurable interconnections 1410, and example storage circuitry 1412. The logic gate circuitry 1408 and the configurable interconnections 1410 are configurable to instantiate one or more operations/functions that may correspond to at least some of the machine readable instructions of FIG. 11and/or other desired operations. The logic gate circuitry 1408 shown in FIG. 14 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1408 to enable configuration of the electrical structures and/or the logic gates to form circuits to perform desired operations/functions. The logic gate circuitry 1408 may include other electrical structures such as look-up tables (LUTs), registers (e.g., flip-flops or latches), multiplexers, etc.

The configurable interconnections 1410 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1408 to program desired logic circuits.

The storage circuitry 1412 of the illustrated example is structured to store result(s) of the one or more of the operations performed by corresponding logic gates. The storage circuitry 1412 may be implemented by registers or the like. In the illustrated example, the storage circuitry 1412 is distributed amongst the logic gate circuitry 1408 to facilitate access and increase execution speed.

The example FPGA circuitry 1400 of FIG. 14 also includes example dedicated operations circuitry 1414. In this example, the dedicated operations circuitry 1414 includes special purpose circuitry 1416 that may be invoked to implement commonly used functions to avoid the need to program those functions in the field. Examples of such special purpose circuitry 1416 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1400 may also include example general purpose programmable circuitry 1418 such as an example CPU 1420 and/or an example DSP 1422. Other general purpose programmable circuitry 1418 may additionally or alternatively be present such as a GPU, an XPU, etc., that can be programmed to perform other operations.

Although FIGS. 13 and 14 illustrate two example implementations of the programmable circuitry 1212 of FIG. 12, many other approaches are contemplated. For example, FPGA circuitry may include an on-board CPU, such as one or more of the example CPU 1420 of FIG. 13. Therefore, the programmable circuitry 1212 of FIG. 12 may additionally be implemented by combining at least the example microprocessor 1300 of FIG. 13 and the example FPGA circuitry 1400 of FIG. 14. In some such hybrid examples, one or more cores 1302 of FIG. 13 may execute a first portion of the machine readable instructions represented by the flowchart(s) of FIG. 11to perform first operation(s)/function(s), the FPGA circuitry 1400 of FIG. 14 may be configured and/or structured to perform second operation(s)/function(s) corresponding to a second portion of the machine readable instructions represented by the flowchart of FIG. 11, and/or an ASIC may be configured and/or structured to perform third operation(s)/function(s) corresponding to a third portion of the machine readable instructions represented by the flowchart of FIG. 11.

It should be understood that some or all of the circuitry of FIG. 12 may, thus, be instantiated at the same or different times. For example, same and/or different portion(s) of the microprocessor 1300 of FIG. 13 may be programmed to execute portion(s) of machine-readable instructions at the same and/or different times. In some examples, same and/or different portion(s) of the FPGA circuitry 1400 of FIG. 14 may be configured and/or structured to perform operations/functions corresponding to portion(s) of machine-readable instructions at the same and/or different times.

In some examples, some or all of the circuitry of FIG. 12 may be instantiated, for example, in one or more threads executing concurrently and/or in series. For example, the microprocessor 1300 of FIG. 13 may execute machine readable instructions in one or more threads executing concurrently and/or in series. In some examples, the FPGA circuitry 1400 of FIG. 14 may be configured and/or structured to carry out operations/functions concurrently and/or in series. Moreover, in some examples, some or all of the circuitry of FIG. 12 may be implemented within one or more virtual machines and/or containers executing on the microprocessor 1300 of FIG. 13.

In some examples, the programmable circuitry 1212 of FIG. 12 may be in one or more packages. For example, the microprocessor 1300 of FIG. 13 and/or the FPGA circuitry 1400 of FIG. 14 may be in one or more packages. In some examples, an XPU may be implemented by the programmable circuitry 1212 of FIG. 12, which may be in one or more packages. For example, the XPU may include a CPU (e.g., the microprocessor 1300 of FIG. 13, the CPU 1420 of FIG. 14, etc.) in one package, a DSP (e.g., the DSP 1422 of FIG. 14) in another package, a GPU in yet another package, and an FPGA (e.g., the FPGA circuitry 1400 of FIG. 14) in still yet another package.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

From the foregoing, it will be appreciated that example systems, apparatus, articles of manufacture, and methods have been disclosed to provide improved heat dissipation. Disclosed systems, apparatus, articles of manufacture, and methods improve the efficiency of a computing device by increasing an efficiency of heat dissipation without increasing a thickness of the device. Disclosed systems, apparatus, articles of manufacture, and methods are accordingly directed to one or more improvement(s) in the operation of a machine such as a computer or other electronic and/or mechanical device.

Example methods, apparatus, systems, and articles of manufacture to provide improved heat dissipation systems are disclosed herein. Further examples and combinations thereof include the following:

Example 1 includes a computing device includes a display, a keyboard, processor circuitry, and a dual-phase heat dissipation system. The dual-phase dissipation system includes a housing defining a chamber, a fluid inlet, and a fluid outlet. The chamber receives a working fluid via the fluid inlet. A pump fluidly couples to the fluid inlet and the fluid outlet of the housing. The pump is to receive the working fluid via the fluid outlet of the housing and increase at least one of a flow rate or volume of the working fluid at the fluid inlet.

Example 2 includes the computing device of example 1, where the housing includes a first plate and a second plate opposite the first plate to define the chamber.

Example 3 includes the computing device of examples 1-2, where the housing further includes a first wick provided on the first plate and a second wick provided on the second plate, at least one of the first wick or the second wick to move working fluid through the chamber via capillary action.

Example 4 includes the computing device of examples 1-3, where the housing further includes a wick on the first plate.

Example 5 includes the computing device of examples 1-4, where the housing includes a primary flow path to enable working fluid to flow from a condensed area toward a heat source.

Example 6 includes the computing device of examples 1-5, further including a bypass flow path between the fluid inlet and the fluid outlet, the bypass flow path to enable working fluid to bypass at least a portion of the primary flow path via the pump to increase a flow rate of the working fluid at the fluid inlet.

Example 7 includes the computing device of examples 1-6, where the bypass flow path includes a pipe having a first end fluidly coupled to the primary flow path of heat dissipation system and a second end fluidly coupled to the pump.

Example 8 includes the computing device of examples 1-7, further including a fluid reservoir fluidly coupled to the pump.

Example 9 includes an electronic device having a housing including a printed circuit board, memory, a processor, and a vapor chamber. The vapor chamber includes a working fluid, a wick structure to passively move the working fluid between a condenser and an evaporator, and a shell to seal the working fluid and the wick structure. A pump fluidly couples with the vapor chamber to increase an amount of working fluid through the wick structure. The device includes processor circuitry to operate the pump in a passive phase of heat dissipation and to operate the pump in an active phase of heat dissipation.

Example 10 includes the electronic device of example 9, further including a fluid reservoir fluidly coupled to the vapor chamber and the pump, the fluid reservoir to store working fluid externally from the vapor chamber.

Example 11 includes the electronic device of examples 9-10, where the pump is to provide the working fluid from the fluid reservoir to the vapor chamber when the pump operates in the active phase of heat dissipation.

Example 12 includes the electronic device of examples 9-11, where the pump is to increase a flow rate of the working fluid through the wick structure when the pump operates in the active phase of heat dissipation.

Example 13 includes the electronic device of examples 9-12, where the wick structure moves the working fluid through the vapor chamber via capillary action.

Example 14 includes the electronic device of examples 9-13, where the pump is a piezoelectric diaphragm pump.

Example 15 includes the electronic device of examples 9-14, wherein the wick structure is positioned along a perimeter of the vapor chamber.

Example 16 includes the electronic device of examples 9-15, where a center area of an evaporator chamber defined by the shell does not include the wick structure.

Example 17 includes an electronic device including a housing, and a thermal management system to dissipate heat generated by one or more components of the electronic device in the housing. The thermal management system includes a vapor chamber including a wick structure to circulate a working fluid in the vapor chamber via capillary action, and a pump fluidly coupled to the vapor chamber. Processor circuitry is to operate the pump in a first mode in response to a first condition of the electronic device exceeding a condition threshold, where operation of the pump in the first mode is to increase a flow rate of the working fluid through the vapor chamber, and operate the pump in a second mode in response to the first condition not exceeding the condition threshold, where operation of the pump in the second mode to reduce a flow rate of the working fluid through the vapor chamber.

Example 18 includes the electronic device of example 17, where the condition threshold is a temperature threshold, and the first condition is a temperature of a central processing unit.

Example 19 includes the electronic device of examples 17-18, where the condition threshold is a fan speed threshold, and the first condition is a speed of a fan of the electronic device.

Example 20 includes the electronic device of examples 17-19, where the vapor chamber includes a wick structure to circulate a working fluid in the vapor chamber via capillary action.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A computing device comprising:
a display;
a keyboard;
processor circuitry; and
a dual-phase heat dissipation system including:
a housing defining a chamber, a fluid inlet and a fluid outlet, the chamber to receive a working fluid via the fluid inlet; and
a pump fluidly coupled to the fluid inlet and the fluid outlet of the housing, the pump to receive the working fluid via the fluid outlet of the housing and increase at least one of a flow rate or volume of the working fluid at the fluid inlet.

2. The computing device of claim 1, wherein the housing includes a first plate and a second plate opposite the first plate to define the chamber.

3. The computing device of claim 2, wherein the housing further includes a first wick provided on the first plate and a second wick provided on the second plate, at least one of the first wick or the second wick to move working fluid through the chamber via capillary action.

4. The computing device of claim 2, wherein the housing further includes a wick on the first plate.

5. The computing device of claim 1, wherein the housing includes a primary flow path to enable working fluid to flow from a condensed area toward a heat source.

6. The computing device of claim 5, further including a bypass flow path between the fluid inlet and the fluid outlet, the bypass flow path to enable working fluid to bypass at least a portion of the primary flow path via the pump to increase a flow rate of the working fluid at the fluid inlet.

7. The computing device of claim 6, wherein the bypass flow path includes a pipe having a first end fluidly coupled to the primary flow path of heat dissipation system and a second end fluidly coupled to the pump.

8. The computing device of claim 6, further including a fluid reservoir fluidly coupled to the pump.

9. An electronic device comprising:
a housing including:
a printed circuit board;
memory;
a processor;
a vapor chamber including:
a working fluid;
a wick structure to passively move the working fluid between a condenser and an evaporator; and
a shell to seal the working fluid and the wick structure;
a pump fluidly coupled with the vapor chamber, the pump to increase an amount of working fluid through the wick structure; and
processor circuitry to operate the pump in a passive phase of heat dissipation and to operate the pump in an active phase of heat dissipation.

10. The electronic device of claim 9, further including a fluid reservoir fluidly coupled to the vapor chamber and the pump, the fluid reservoir to store working fluid externally from the vapor chamber.

11. The electronic device of claim 10, wherein the pump is to provide the working fluid from the fluid reservoir to the vapor chamber when the pump operates in the active phase of heat dissipation.

12. The electronic device of claim 9, wherein the pump is to increase a flow rate of the working fluid through the wick structure when the pump operates in the active phase of heat dissipation.

13. The electronic device of claim 9, wherein the wick structure moves the working fluid through the vapor chamber via capillary action.

14. The electronic device of claim 9, wherein the pump is a piezoelectric diaphragm pump.

15. The electronic device of claim 9, wherein the wick structure is positioned along a perimeter of the vapor chamber.

16. The electronic device of claim 15, wherein a center area of an evaporator chamber defined by the shell does not include the wick structure.

17. An electronic device comprising:
a housing;
a thermal management system to dissipate heat generated by one or more components of the electronic device in the housing, the thermal management system including:
a vapor chamber including a wick structure to circulate a working fluid in the vapor chamber via capillary action; and
a pump fluidly coupled to the vapor chamber; and
processor circuitry to:
operate the pump in a first mode in response to a first condition of the electronic device exceeding a condition threshold, operation of the pump in the first mode is to increase a flow rate of the working fluid through the vapor chamber; and
operate the pump in a second mode in response to the first condition not exceeding the condition threshold, operation of the pump in the second mode to reduce a flow rate of the working fluid through the vapor chamber.

18. The electronic device of claim 17, wherein the condition threshold is a temperature threshold, and the first condition is a temperature of a central processing unit.

19. The electronic device of claim 17, wherein the condition threshold is a fan speed threshold, and the first condition is a speed of a fan of the electronic device.

20. The electronic device of claim 17, wherein the vapor chamber includes a wick structure to circulate a working fluid in the vapor chamber via capillary action.
